(19) United States
(12) Patent Application Publication
(10) Pub. No.: US 2024/0088340 A1
(43) Pub. Date: Mar. 14, 2024

(54) DISPLAY DEVICE AND MANUFACTURING METHOD OF THE SAME

(71) Applicant: Samsung Display Co., LTD., Yongin-si (KR)

(72) Inventors: Yong Tae CHO, Yongin-si (KR); Ki Nyeng KANG, Yongin-si (KR); Veidhes BASRUR, Yongin-si (KR); Jin Taek KIM, Yongin-si (KR); Ock Soo SON, Yongin-si (KR)

(21) Appl. No.: 18/457,840

(22) Filed: Aug. 29, 2023

(30) Foreign Application Priority Data
Sep. 13, 2022 (KR) 10-2022-0114748

(51) Int. Cl. H01L 33/62; H01L 25/075; H01L 25/16; H01L 27/12; H01L 33/38; H01L 33/40

(52) U.S. Cl. CPC H01L 33/62; H01L 25/0753; H01L 25/167; H01L 27/1218; H01L 27/1262; H01L 33/38; H01L 33/40; H01L 2933/0016; H01L 2933/0066

(57) ABSTRACT

A display device includes a substrate including a display area and a pad area, a circuit element layer on the substrate, and an alignment electrode layer on the circuit element layer, wherein the circuit element layer includes a thin film transistor in the display area, and a pad electrode in the pad area, the alignment electrode layer includes a first alignment electrode and a second alignment electrode spaced from each other in the display area, and a pad upper electrode includes a first opening exposing the pad electrode in the pad area, and a light emitting element is on a space between the first alignment electrode and the second alignment electrode that are spaced from each other.

### CROSS-REFERENCE TO RELATED APPLICATION

This application claims priority to and the benefit of Korean Patent Application No. 10-2022-0114748 filed on Sep. 13, 2022, in the Korean Intellectual Property Office, the entire content of which is incorporated by reference herein.

### BACKGROUND

### 1. Field

The present disclosure relates to a display device and a manufacturing method of the same.

### 2. Description of the Related Art

The importance of display devices has increased with the development of multimedia. Accordingly, various types of display devices such as an organic light emitting diode (OLED) display and a liquid crystal display (LCD) have been used.

The display devices are devices displaying images, and include display panels such as organic light emitting display panels or liquid crystal display panels. Among them, the light emitting display panel may include light emitting elements such as light emitting diodes (LEDs), and examples of such light emitting diodes include organic light emitting diodes (OLEDs) that use an organic material as a fluorescent material, inorganic light emitting diodes that use an inorganic material as a fluorescent material, and the like.

An inorganic light emitting diode that uses an inorganic semiconductor as a fluorescent material has durability even in a high temperature environment, and has an advantage that efficiency of blue light may be higher than that of an organic light emitting diode.

### SUMMARY

Aspects and features of embodiments of the present disclosure provide a display device in which device reliability of a pad part is improved.

Aspects and features of embodiments of the present disclosure also provide a manufacturing method of a display device in which device reliability of a pad part is improved.

However, aspects and features of embodiments of the present disclosure are not restricted to those set forth herein. The above and other aspects of the present disclosure will become more apparent to one of ordinary skill in the art to which the present disclosure pertains by referencing the detailed description of the present disclosure given below.

According to one or more embodiments of the present disclosure, a display device includes a substrate including a display area and a pad area, a circuit element layer on the substrate, and an alignment electrode layer on the circuit element layer, wherein the circuit element layer includes a thin film transistor in the display area, and a pad electrode in the pad area, the alignment electrode layer includes a first alignment electrode and a second alignment electrode spaced from each other in the display area, and a pad upper electrode including a first opening exposing the pad electrode in the pad area, and a light emitting element is located in a space between the first alignment electrode and the second alignment electrode that are spaced from each other.

In one or more embodiments, the display device further includes a passivation layer between the circuit element layer and the alignment electrode layer, wherein the passivation layer includes a second opening exposing the pad electrode.

In one or more embodiments, the passivation layer includes an overlapping part on an upper surface of the pad electrode and forming the second opening, and the pad upper electrode covers a portion of the upper surface of the pad electrode exposed by the second opening beyond the overlapping part.

In one or more embodiments, a width of the first opening is smaller than a width of the second opening.

In one or more embodiments, the pad upper electrode includes a peeling cross section of an irregular pattern at a portion forming the first opening, and the peeling cross section overlaps the upper surface of the pad electrode exposed by the second opening.

In one or more embodiments, an adhesive force between the pad upper electrode and the pad electrode is smaller than an adhesive force between the pad upper electrode and the overlapping part.

In one or more embodiments, the pad upper electrode includes aluminum (Al), and the pad electrode includes copper (Cu).

In one or more embodiments, the passivation layer includes an overlapping part on an upper surface of the pad electrode and forming the second opening, and the pad upper electrode covers a portion of an upper surface of the overlapping part.

In one or more embodiments, a width of the first opening is smaller than a width of the second opening.

In one or more embodiments, the pad upper electrode includes a peeling cross section of an irregular pattern at a portion forming the first opening, and the peeling cross section overlaps the overlapping part.

In one or more embodiments, the display device further includes a first insulating layer on the alignment electrode layer, wherein the first insulating layer includes a third opening exposing the pad electrode.

In one or more embodiments, the display device further includes an external bank on the first insulating layer and defining an emission area in which the light emitting element is located.

In one or more embodiments, the thin film transistor includes a semiconductor layer, a gate electrode overlapping the semiconductor layer, and source and drain electrodes electrically connected to the semiconductor layer, and the pad electrode includes a same material as the source/drain electrodes.

In one or more embodiments, the display device further includes a metal pattern on an upper surface of the pad electrode exposed by the first opening, wherein the metal pattern includes a same material as the pad upper electrode.

According to one or more embodiments of the present disclosure, a manufacturing method of a display device includes: preparing a substrate in which a display area and a pad area are defined, forming a thin film transistor located on the substrate and overlapping the display area and a pad electrode located on the substrate and overlapping the pad area, forming a via insulating layer in the display area and covering the thin film transistor, forming a first alignment electrode and a second alignment electrode spaced from each other on the via insulating layer in the display area and forming a pad upper electrode material layer covering the pad electrode in the pad area, forming a pad upper electrode including a first opening exposing the pad electrode by peeling off a portion of the pad upper electrode material layer overlapping the pad electrode, and disposing a light emitting element on a space between the first alignment electrode and the second alignment electrode that are spaced from each other.

In one or more embodiments, the method further includes forming a first insulating layer covering the first alignment electrode and the second alignment electrode in the display area and including a second opening exposing the pad upper electrode material layer in the pad area.

In one or more embodiments, the method further includes forming an external bank on the first insulating layer, the external bank defining an emission area in which the light emitting element is located, the forming of the pad upper electrode is performed after the forming of the external bank.

In one or more embodiments, the forming of the thin film transistor and the pad electrode includes forming a passivation layer covering the thin film transistor in the display area and including a second opening exposing a portion of the pad electrode in the pad area, and the pad upper electrode material layer covers the passivation layer and a portion of the pad electrode exposed by the second opening in the pad area.

In one or more embodiments, an adhesive force between the pad upper electrode material layer and the pad electrode is smaller than an adhesive force between the pad upper electrode material layer and the passivation layer.

In one or more embodiments, the peeling-off of the portion of the pad upper electrode material layer overlapping the pad electrode is performed by a mechanical peeling using a tape.

With a display device according to one or more embodiments, device reliability of a pad part may be improved.

With a manufacturing method of a display device according to one or more embodiments, a display device in which device reliability of a pad part is improved may be provided.

The effects, aspects, and features of the present disclosure are not limited to the aforementioned effects, aspects, and features and various other effects, aspects, and features are included in the present disclosure.

### BRIEF DESCRIPTION OF THE DRAWINGS

The above and other aspects and features of the present disclosure will become more apparent by describing in detail embodiments thereof with reference to the attached drawings, in which:

FIG. 1 is a schematic plan view of a display device according to one or more embodiments;

FIG. 2 is a schematic layout view illustrating a plurality of lines of the display device according to one or more embodiments;

FIG. 3 is an equivalent circuit diagram of one sub-pixel according to one or more embodiments;

FIG. 4 is a plan view illustrating a structure of a pixel of the display device according to one or more embodiments;

FIG. 5 is a perspective cutaway view illustrating a structure of a light emitting element of FIG. 4;

FIG. 6 is an enlarged view of an area A1 of FIG. 4;

FIG. 7 is a cross-sectional view illustrating a schematic cross section taken along the line X1-X1′ of FIG. 6 and a schematic cross-section of a pad part of the display device according to one or more embodiments;

FIG. 8 is an enlarged view of an area A2 of FIG. 7;

FIGS. 9 to 17 are a flowchart and cross-sectional views for describing a manufacturing process of a display device according to one or more embodiments;

FIG. 18 is a cross-sectional view illustrating a structure of a pad part of a display device according to one or more embodiments;

FIG. 19 is a cross-sectional view illustrating a structure of a pad part of a display device according to one or more embodiments; and

FIG. 20 is a cross-sectional view illustrating a structure of a pad part of a display device according to one or more embodiments.

### DETAILED DESCRIPTION

The present disclosure will now be described more fully hereinafter with reference to the accompanying drawings, in which embodiments of the present disclosure are shown. The present disclosure may, however, be embodied in different forms and should not be construed as limited to the embodiments set forth herein. Rather, these embodiments are provided so that the present disclosure will be thorough and complete, and will fully convey the scope of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

Hereinafter, specific embodiments will be described with reference to the accompanying drawings.

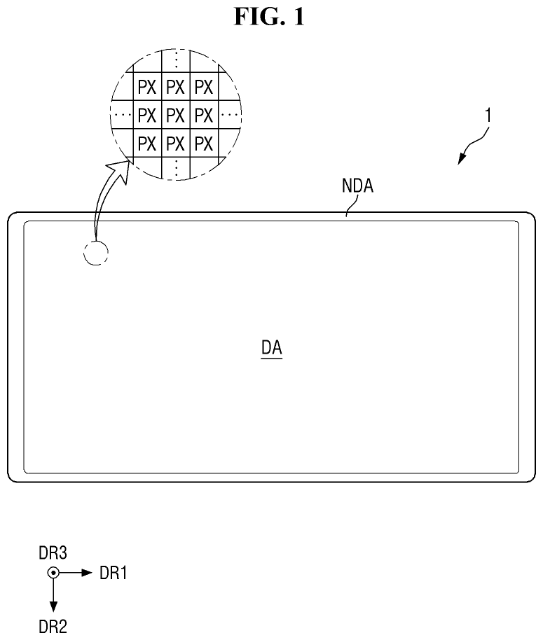

FIG. 1 is a schematic plan view of a display device according to one or more embodiments.

In FIG. 1, a first direction DR1, a second direction DR2, and a third direction DR3 are defined. The first direction DR1 and the second direction DR2 may be perpendicular to each other, the first direction DR1 and the third direction DR3 may be perpendicular to each other, and the second direction DR2 and the third direction DR3 may be perpendicular to each other. It may be understood that the first direction DR1 refers to a transverse direction in the drawing, the second direction DR2 refers to a longitudinal direction in the drawing, and the third direction DR3 refers to an upward and downward direction (i.e., a thickness direction) in the drawing.

In the following specification, unless otherwise specified, the term “direction” may refer to both directions toward both sides extending along the direction. In addition, when both “directions” extending to both sides need to be distinguished from each other, one side will be referred to as “one side in the direction” and the other side will be referred to as “the other side in the direction”. In FIG. 1, a direction to which an arrow indicating a direction is directed will be referred to as one side, and a direction opposite to such a direction will be referred to as the other side.

In addition, for convenience of explanation, in referring to a display device 1 or surfaces of respective members constituting the display device 1, one surface facing one side in a direction in which an image is displayed, that is, the third direction DR3 will be referred to as an upper surface, and the other surface opposite to the one surface will be referred to as a lower surface. However, the present disclosure is not limited thereto, and the one surface and the other surface of the member may be referred to as a front surface and a rear surface, respectively, or may be referred to as a first surface or a second surface, respectively. In addition, in describing relative positions of the respective members of the display device 1, one side in the third direction DR3 may be referred to as an upper portion and the other side in the third direction DR3 may be referred to as a lower portion.

Referring to FIG. 1, a display device 1 displays a moving image or a still image. The display device 1 may refer to all electronic devices that provide display screens. For example, televisions, laptop computers, monitors, billboards, the Internet of Things (IoT), mobile phones, smartphones, tablet personal computers (PCs), electronic watches, smart watches, watch phones, head mounted displays, mobile communication terminals, electronic notebooks, electronic books, portable multimedia players (PMPs), navigation devices, game machines, digital cameras, camcorders, and the like, which provide display screens, may be included in the display device 1.

The display device 1 includes a display panel providing the display screen. Examples of the display panel may include an inorganic light emitting diode display panel, an organic light emitting display panel, a quantum dot light emitting display panel, a plasma display panel, a field emission display panel, and the like. Hereinafter, a case where an inorganic light emitting diode display panel is applied as an example of the display panel will be described by way of example, but the present disclosure is not limited thereto, and the same technical spirit may be applied to other display panels if applicable.

A shape of the display device 1 may be variously modified. For example, the display device 1 may have a shape such as a rectangular shape with a width greater than a length, a rectangular shape with a length greater than a width, a square shape, a rectangular shape with rounded corners (vertices), other polygonal shapes, or a circular shape. A shape of a display area DA of the display device 1 may also be similar to an overall shape of the display device 1. In FIG. 1, the display device 1 having a rectangular shape with a great length in the second direction DR2 is illustrated.

The display device 1 may include a display area DA and a non-display area NDA along an edge or periphery of the display area DA. The display area DA is an area in which an image may be displayed, and the non-display area NDA is an area in which no image is displayed. The display area DA may also be referred to as an active area, and the non-display area NDA may also be referred to as a non-active area. The display area DA may occupy substantially the center (e.g., the central region) of the display device 1.

The display area DA may include a plurality of pixels PX. The plurality of pixels PX may be arranged in a matrix direction. For example, the plurality of pixels PX may be arranged along rows and columns of a matrix. A shape of each pixel PX may be a rectangular shape or a square shape in a plan view, but is not limited thereto, and may also be a rhombic shape of which each side is inclined with respect to one direction. The respective pixels PX may be alternately arranged in a stripe type or an island type. In addition, each of the pixels PX may include one or more light emitting elements emitting light of a specific wavelength band to display a specific color.

The non-display area NDA may be disposed around the display area DA. The non-display area NDA may completely or partially surround the display area DA. The display area DA may have a rectangular shape, and the non-display areas NDA may be disposed adjacent to four sides of the display area DA. The non-display areas NDA may constitute a bezel of the display device 1. Lines or circuit drivers included in the display device 1 may be disposed or external devices may be mounted, in each of the non-display areas NDA.

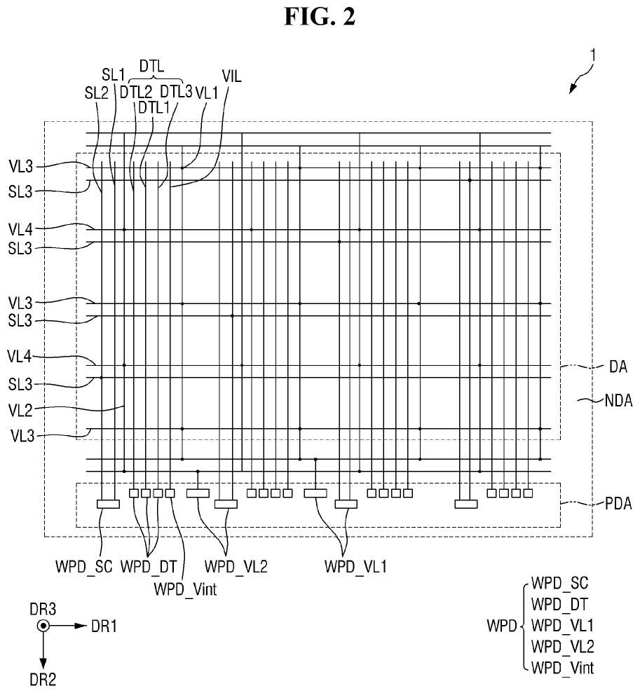

FIG. 2 is a schematic layout view illustrating a plurality of lines of the display device according to one or more embodiments.

Referring to FIG. 2, the display device 1 may include a plurality of lines. The display device 1 may include a plurality of scan lines SL: SL1, SL2, and SL3, a plurality of data lines DTL: DTL1, DTL2, and DTL3, initialization voltage lines VIL, and a plurality of voltage lines VL: VL1, VL2, VL3, and VL4. In addition, in one or more embodiments, other lines may be further disposed in the display device 1. The plurality of lines may include lines formed of a first conductive layer and extending in the second direction DR2 and lines formed of a third conductive layer and extending in the first direction DR1. However, extension directions of the respective lines are not limited thereto.

First scan lines SL1 and second scan lines SL2 may be disposed to extend in the second direction DR2. The first scan line SL1 and the second scan line SL2 may be disposed in a state in which they are adjacent to each other, and may be disposed to be spaced from the other first scan lines SL1 and second scan lines SL2 in the first direction DR1. The first scan lines SL1 and the second scan lines SL2 may be connected to scan wiring pads WPD_SC connected to a scan driver. The first scan lines SL1 and the second scan lines SL2 may be disposed to extend from a pad area PDA disposed in the non-display area NDA to the display area DA.

A third scan line SL3 may be disposed to extend in the first direction DR1, and may be disposed to be spaced from the other third scan lines SL3 in the second direction DR2. One third scan line SL3 may be connected to one or more first scan lines SL1 or one or more second scan lines SL2. The plurality of scan lines SL may have a mesh structure in the entirety of the display area DA, but are not limited thereto.

In one or more embodiments, the term ‘connection’ as used herein may not only mean that any one member is connected to another member through physical contact with another member, but may also mean that any one member is connected to another member through the other member. In addition, it may be understood that any one portion and another portion as one integrated member are connected to each other due to the integrated member. Furthermore, a connection between any one member and another member may be interpreted as the meaning including an electrical connection through the other member in addition to a connection through direct contact therebetween.

The data lines DTL may be disposed to extend in the second direction DR2. The data lines DTL include first data lines DTL1, second data lines DTL2, and third data lines DTL3, and one first to third data lines DTL1, DTL2, and DTL3 are disposed adjacent to each other while forming one pair. Each of the data lines DTL1, DTL2, and DTL3 may be disposed to extend from the pad area PDA disposed in the non-display area NDA to the display area DA. However, the present disclosure is not limited thereto, and the plurality of data lines DTL may also be disposed to be spaced from each other at equal intervals between a first voltage line VL1 and a second voltage line VL2 to be described later.

The initialization voltage lines VIL may be disposed to extend in the second direction DR2. The initialization voltage line VIL may be disposed between the data lines DTL and the first voltage line VL1. The initialization voltage lines VIL may be disposed to extend from the pad area PDA disposed in the non-display area NDA to the display area DA.

First voltage lines VL1 and second voltage lines VL2 are disposed to extend in the second direction DR2, and third voltage lines VL3 and fourth voltage lines VL4 are disposed to extend in the first direction DR1. The first voltage lines VL1 and the second voltage lines VL2 may be alternately disposed along the first direction DR1, and the third voltage lines VL3 and the fourth voltage lines VL4 may be alternately disposed along the second direction DR2. The first voltage lines VL1 and the second voltage lines VL2 may be disposed to extend in the second direction DR2 to cross the display area DA, and some of each of the third voltage lines VL3 and the fourth voltage lines VL4 may be disposed in the display area DA and the others of each of the third voltage lines VL3 and the fourth voltage lines VL4 may be disposed in the non-display areas NDA positioned on both sides of the display area DA in the second direction DR2. The first voltage line VL1 and the second voltage line VL2 may be formed of a first conductive layer, and the third voltage line VL3 and the fourth voltage line VL4 may be formed of a third conductive layer disposed at a different layer from the first conductive layer. The first voltage line VL1 is connected to at least one third voltage line VL3, and the second voltage line VL2 is connected to at least one fourth voltage line VL4, such that the plurality of voltage lines VL may have a mesh structure in the entirety of the display area DA. However, the present disclosure is not limited thereto.

The first scan line SL1, the second scan line SL2, the data line DTL, the initialization voltage line VIL, the first voltage line VL1, and the second voltage line VL2 may be electrically connected to at least one wiring pad WPD. Each wiring pad WPD may be disposed in the non-display area NDA. In one or more embodiments, each of the wiring pads WPD may be disposed in the pad area PDA positioned on the lower side of the display area DA, which is the other side of the display area DA in the second direction DR2. The first scan line SL1 and the second scan line SL2 are connected to a scan wiring pad WPD_SC disposed in the pad area PDA, and the plurality of data lines DTL are connected to different data wiring pads WPD_DT, respectively. The initialization voltage line VIL is connected to an initialization wiring pad WPD_Vint, the first voltage line VL1 is connected to a first voltage wiring pad WPD_VL1, and the second voltage line VL2 is connected to a second voltage wiring pad WPD_VL2. An external device may be mounted on the wiring pad WPD. The external device may be mounted on the wiring pad WPD through an anisotropic conductive film, ultrasonic bonding, or the like. It has been illustrated in FIG. 2 that each of the wiring pads WPD is disposed in the pad area PDA disposed on the lower side of the display area DA, but the present disclosure is not limited thereto. Some of a plurality of wiring pads WPD may also be disposed on the upper side of the display area DA or on any one of the left side and the right side of the display area DA.

Each pixel PX or sub-pixel SPXn (n is an integer of 1 to 3) of the display device 1 includes a pixel driving circuit. The above-described lines may apply driving signals to the respective pixel driving circuits while passing through the respective pixels PX or around the respective pixels PX. The pixel driving circuit may include a transistor and a capacitor. The numbers of transistors and capacitors in each pixel driving circuit may be variously modified. According to one or more embodiments, each sub-pixel SPXn of the display device 1 may have a 3T1C structure in which the pixel driving circuit includes three transistors and one capacitor. Hereinafter, the pixel driving circuit will be described using the 3T1C structure as an example, but the present disclosure is not limited thereto, and various other modified structures such as a 2T1C structure, a 7T1C structure, and a 6T1C structure may be applied.

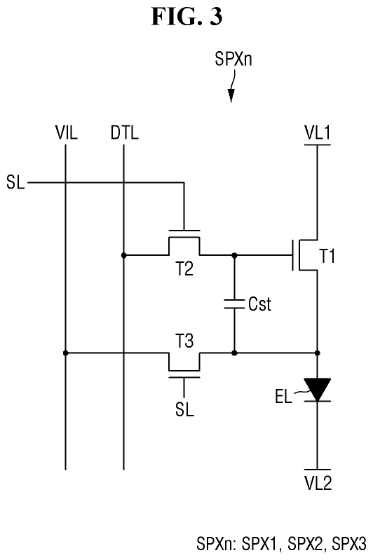

FIG. 3 is an equivalent circuit diagram of one sub-pixel according to one or more embodiments.

Referring to FIG. 3, each sub-pixel SPXn of the display device 1 according to one or more embodiments includes three transistors T1, T2, and T3 and one storage capacitor Cst, in addition to a light emitting diode EL.

The light emitting diode EL emits light according to a current supplied through a first thin film transistor T1. The light emitting diode EL includes a first electrode, a second electrode, and at least one light emitting element disposed between the first electrode and the second electrode. The light emitting element may emit light of a specific wavelength band by electrical signals transferred from the first electrode and the second electrode.

One end of the light emitting diode EL may be connected to a source electrode of the first thin film transistor T1, and the other end of the light emitting diode EL may be connected to a second voltage line VL2 to which a low potential voltage (hereinafter, referred to as a second source voltage) lower than a high potential voltage (hereinafter, referred to as a first source voltage) of a first voltage line VL1 is supplied.

The first thin film transistor T1 adjusts a current flowing from the first voltage line VL1 to which the first source voltage is supplied to the light emitting diode EL according to a voltage difference between a gate electrode and the source electrode of the first thin film transistor T1 thereof. As an example, the first thin film transistor T1 may be a driving transistor for driving the light emitting diode EL. The gate electrode of the first thin film transistor T1 may be connected to a source electrode of a second thin film transistor T2, the source electrode of the first thin film transistor T1 may be connected to the first electrode of the light emitting diode EL, and a drain electrode of the first thin film transistor T1 may be connected to the first voltage line VL1 to which the first source voltage is applied.

The second thin film transistor T2 is turned on by a scan signal of a scan line SL to connect a data line DTL to the gate electrode of the first thin film transistor T1. A gate electrode of the second thin film transistor T2 may be connected to the scan line SL, the source electrode of the second thin film transistor T2 may be connected to the gate electrode of the first thin film transistor T1, and a drain electrode of the second thin film transistor T2 may be connected to the data line DTL.

A third transistor T3 is turned on by a scan signal of the scan line SL to connect an initialization voltage line VIL to one end of the light emitting diode EL. A gate electrode of the third transistor T3 may be connected to the scan line SL, a drain electrode of the third transistor T3 may be connected to the initialization voltage line VIL, and a source electrode of the third transistor T3 may be connected to one end of the light emitting diode EL or the source electrode of the first thin film transistor T1.

In one or more embodiments, the source electrode and the drain electrode of each of the transistors T1, T2, and T3 are not limited to those described above, and vice versa. Each of the transistors T1, T2, and T3 may be formed as a thin film transistor. It has been mainly described in FIG. 3 that the respective transistors T1, T2, and T3 are formed as N-channel metal oxide semiconductor field effect transistors (MOSFETs), but the present disclosure is not limited thereto. That is, the respective transistors T1, T2, and T3 may be formed as P-channel MOSFETs or some of the transistors T1, T2, and T3 may be formed as N-channel MOSFETs and the other ones of the transistors T1, T2, and T3 may be formed as P-channel MOSFETs.

The storage capacitor Cst is formed between the gate electrode and the source electrode of the first thin film transistor T1. The storage capacitor Cst stores a difference voltage between a gate voltage and a source voltage of the first thin film transistor T1.

In one or more embodiments of FIG. 3, the gate electrode of the second thin film transistor T2 may be connected to the scan line SL1, and the gate electrode of the third transistor T3 may be connected to the scan line SL2. In other words, the second thin film transistor T2 and the third transistor T3 may be turned on by a scan signal applied from the different scan lines. However, the present disclosure is not limited thereto, and the second thin film transistor T2 and the third transistor T3 may be connected to the same scan lines and turned on by scan signals applied from the same scan lines.

Hereinafter, a structure of the pixel PX of the display device 1 according to one or more embodiments will be described.

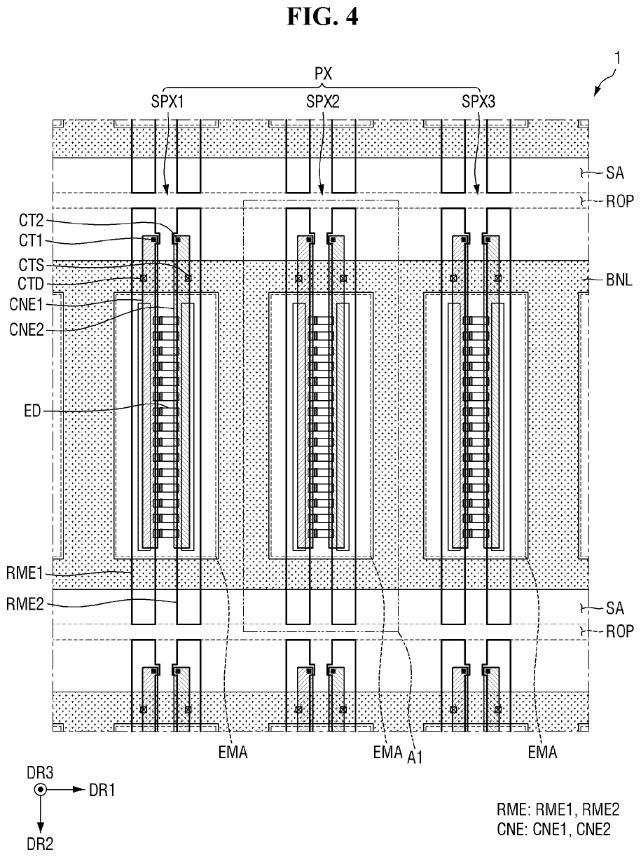

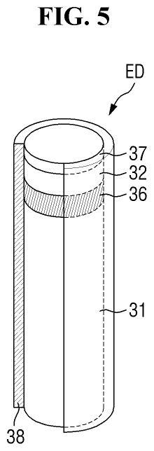

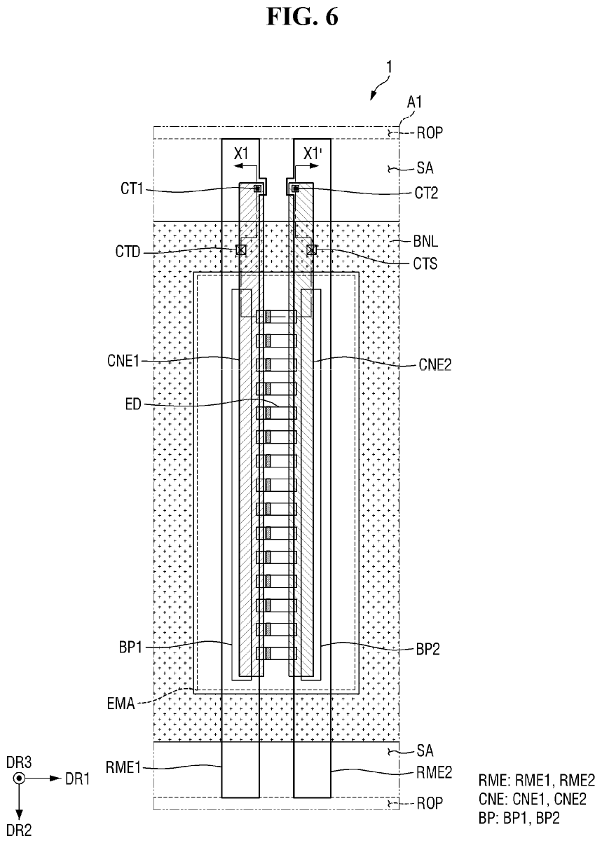

FIG. 4 is a plan view illustrating a structure of a pixel of the display device according to one or more embodiments. FIG. 5 is a perspective cutaway view illustrating a structure of a light emitting element of FIG. 4. FIG. 6 is an enlarged view of area A1 of FIG. 4.

Referring to FIGS. 4 and 6, each of the pixels PX of the display device 1 may include a plurality of sub-pixels SPXn. For example, one pixel PX may include a first sub-pixel SPX1, a second sub-pixel SPX2, and a third sub-pixel SPX3. The first sub-pixel SPX1 may emit light of a first color, the second sub-pixel SPX2 may emit light of a second color, and the third sub-pixel SPX3 may emit light of a third color. As an example, the first color may be blue, the second color may be green, and the third color may be red. However, the present disclosure is not limited thereto, and the respective sub-pixels SPXn may also emit light of the same color. In one or more embodiments, the respective sub-pixels SPXn may emit blue light. It has been illustrated in FIG. 4 that one pixel PX includes three sub-pixels SPXn, but the present disclosure is not limited thereto, and the pixel PX may include a larger number of sub-pixels SPXn. Hereinafter, for convenience of explanation, it will be mainly described that one pixel PX includes three sub-pixels SPXn.

The first sub-pixel SPX1, the second sub-pixel SPX2, and the third sub-pixel SPX3 may be sequentially arranged toward one side along the first direction DR1. For example, the first sub-pixel SPX1 may be disposed on one side of the third sub-pixel SPX3 in the first direction DR1. Accordingly, one pixel PX and at least one of sub-pixels SPXn of the one pixel PX may neighbor to at least one of sub-pixels SPXn of a pixel PX neighboring to the one pixel PX. For example, in FIG. 4, a third sub-pixel SPX3 of a pixel PX disposed on the other side of the first direction DR1 may neighbor to a first sub-pixel SPX1 of a pixel PX neighboring to the pixel PX disposed on the other side of the first direction DR1 on one side of the first direction DR1.

Each of the sub-pixels SPXn of the display device 1 may include an emission area EMA and a non-emission area. The emission area EMA may be an area in which light emitting elements ED are disposed to emit light of a specific wavelength band. The non-emission area may be an area in which the light emitting elements ED are not disposed and light emitted from the light emitting elements ED does not arrive, and thus, the light is not emitted.

The emission area EMA may be defined by an external bank BNL. In other words, the emission area EMA may be a space surrounded by the external bank BNL. In one or more embodiments, the emission area EMA may have a rectangular shape including short sides in the first direction DR1 and long sides in the second direction DR2, but is not limited thereto.

The emission area EMA may include an area in which the light emitting elements ED are disposed and an area which is adjacent to the light emitting elements ED and in which the light emitted from the light emitting elements ED is emitted. For example, the emission area EMA may also include an area in which the light emitted from the light emitting elements ED is reflected or refracted by other members and then emitted. A plurality of light emitting elements ED may be disposed in each sub-pixel SPXn, and an emission area including an area in which the plurality of light emitting elements ED are disposed and an area adjacent to the plurality of light emitting elements ED may be formed.

It has been illustrated in FIG. 4 that the emission areas EMA of the respective sub-pixels SPXn have a uniform area, but the present disclosure is not limited thereto. In one or more embodiments, the respective emission areas EMA of the respective sub-pixels SPXn may also have different areas depending on colors or wavelength bands of light emitted from the light emitting elements ED disposed in the corresponding sub-pixels SPXn.

Each sub-pixel SPXn may further include a sub-area SA disposed in the non-emission area. The sub-area SA may be an area divided according to an arrangement of an alignment electrode layer RME. The sub-areas SA may be disposed on one side and the other side of the emission area EMA in the second direction DR2. The emission areas EMA may be alternately arranged along the first direction DR1, and the sub-areas SA may extend in the first direction DR1. Each of a plurality of emission areas EMA and sub-areas SA may be alternately and repeatedly disposed along the second direction DR2. The plurality of emission areas EMA may be disposed between the sub-areas SA, respectively.

The sub-area SA may be an area shared by sub-pixels SPXn adjacent to each other in the first direction DR1. For example, the first sub-pixel SPX1, the second sub-pixel SPX2, and the third sub-pixel SPX3 may share the sub-area SA with each other. In addition, the sub-area SA may be an area shared by sub-pixels SPXn adjacent to each other in the second direction DR2. For example, sub-areas SA disposed on both sides of the external bank BNL in the second direction DR2 as illustrated in FIG. 4 may be shared by a sub-pixel SPXn illustrated in FIG. 4 and sub-pixels SPXn that are not illustrated in FIG. 4 and are adjacent to the sub-pixel SPXn in the second direction DR2.

Light is not emitted in the sub-areas SA because the light emitting elements ED are not disposed in the sub-areas SA, but portions of the alignment electrode layer RME disposed in each of the sub-pixels SPXn may be disposed in the sub-areas SA. The alignment electrode layers RME disposed in different sub-pixels SPXn may be disposed to be separated from each other in a separation part ROP of the sub-area SA.

The alignment electrode layer RME and connection electrodes CNE have a shape that extend in the second direction DR2, and are disposed for each sub-pixel SPXn.

The alignment electrode layer RME may include a first alignment electrode RME1 and a second alignment electrode RME2 sequentially arranged toward one side of the first direction DR1 per one sub-pixel SPXn in the display area DA. The first alignment electrode RME1 and the second alignment electrode RME2 may be disposed to be spaced from each other in the first direction DR1.

The first alignment electrode RME1 may be disposed on the other side of the emission area EMA in the first direction DR1. For example, the first alignment electrode RME1 may be disposed to be spaced from a portion of the external bank BNL forming a side of the other side of the emission area EMA in the first direction DR1, in the first direction DR1.

The first alignment electrode RME1 may have a shape in which it extends in the second direction DR2. In one or more embodiments, the first alignment electrode RME1 may have a rectangular profile in a plan view, but is not limited thereto. It has been illustrated in FIGS. 4 and 6 that the first alignment electrode RME1 has a rectangular profile in a plan view.

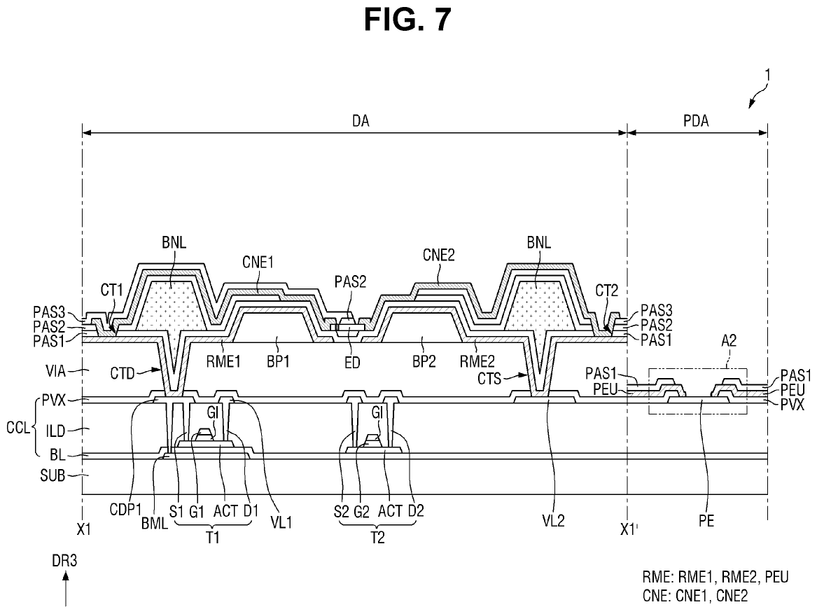

The first alignment electrode RME1 may be electrically connected to a circuit element layer CCL (see FIG. 7) to be described later through a first electrode contact hole CTD. The first alignment electrode RME1 may receive the above-described first source voltage applied through the first electrode contact hole CTD.

The second alignment electrode RME2 may be disposed on one side of the first alignment electrode RME1 in the first direction DR1. The second alignment electrode RME2 may be disposed on the other side of the emission area EMA in the first direction DR1. For example, the second alignment electrode RME2 may be disposed to be spaced from a portion of the external bank BNL forming a side of one side of the emission area EMA in the first direction DR1, in the first direction DR1.

The second alignment electrode RME2 may have a shape in which it extends in the second direction DR2. In one or more embodiments, the second alignment electrode RME2 may have a rectangular profile in a plan view, but is not limited thereto. It has been illustrated in FIGS. 4 and 6 that the second alignment electrode RME2 has a rectangular profile in a plan view.

The second alignment electrode RME2 may be electrically connected to a circuit element layer CCL (see FIG. 7) to be described later through a second electrode contact hole CTS. The second alignment electrode RME2 may receive the above-described second source voltage applied through the second electrode contact hole CTS.

In one or more embodiments, the first electrode contact hole CTD and the second electrode contact hole CTS may not overlap the emission area EMA. In one or more embodiments, the first electrode contact hole CTD and the second electrode contact hole CTS may be disposed to overlap the external bank BNL, but are not limited thereto. For example, the first electrode contact hole CTD and the second electrode contact hole CTS may be disposed on the sub-area SA. It has been illustrated in FIGS. 4 and 6 that the first electrode contact hole CTD and the second electrode contact hole CTS overlap the external bank BNL.

A plurality of internal banks BP may be disposed below each of the alignment electrodes RME1 and RME2. The plurality of internal banks BP may be disposed in the emission area EMA of the sub-pixel SPXn. The plurality of internal banks BP may include a first internal bank BP1 and a second internal bank BP2 each having a rectangular shape, in a plan view, in which they extend in the second direction DR2. The first internal bank BP1 and the second internal bank BP2 may be disposed to be spaced from each other in the first direction DR1.

The first internal bank BP1 may be disposed below the first alignment electrode RME1 within the emission area EMA, and the second internal bank BP2 may be disposed below the second alignment electrode RME2 in the emission area EMA.

In one or more embodiments, the alignment electrodes RME1 and RME2 may completely cover the respective internal banks BP disposed below the respective alignment electrodes RME1 and RME2 in the emission area EMA, but are not limited thereto. For example, the alignment electrodes RME1 and RME2 may also cover only portions of the respective internal banks BP disposed below the respective alignment electrodes RME1 and RME2 in the emission area EMA. It has been illustrated in FIG. 6 that the alignment electrodes RME1 and RME2 completely cover the respective internal banks BP disposed below the respective alignment electrodes RME1 and RME2 in the emission area EMA.

A plurality of alignment electrodes RME1 and RME2 may be spaced from each other in the first direction DR1 to provide a space on which the light emitting elements ED are disposed. For example, the light emitting elements ED may be disposed on a space between the first alignment electrode RME1 and the second alignment electrode RME2 that are spaced from each other.

Referring to FIG. 5, the light emitting element ED may be a light emitting diode. Specifically, the light emitting element ED may be an inorganic light emitting diode having a size of a nanometer to a micrometer scale and made of an inorganic material. The light emitting elements ED may be aligned between two electrodes in which polarities are formed when an electric field is formed in a specific direction between the two electrodes facing each other.

The light emitting element ED according to one or more embodiments may have a shape in which it extends in one direction. The light emitting element ED may have a shape such as a cylindrical shape, a rod shape, a wire shape, or a tube shape. However, the light emitting element ED is not limited to having the shape described above, and may have various shapes. For example, the light emitting element ED may have a polygonal prismatic shape such as a cubic shape, a rectangular parallelepiped shape, or a hexagonal prismatic shape or have a shape in which it extends in one direction and has partially inclined outer surfaces.

The light emitting element ED may include a semiconductor layer doped with any conductivity-type (e.g., p-type or n-type) dopant. The semiconductor layer may receive an electrical signal applied from an external power source to emit light of a specific wavelength band. The light emitting element ED may include a first semiconductor layer 31, a second semiconductor layer 32, a light emitting layer 36, an electrode layer 37, and an insulating film 38.

The first semiconductor layer 31 may be an n-type semiconductor. The first semiconductor layer 31 may include a semiconductor material having a chemical formula of AlₓGa_{y}In_{1-x-y}N (0≤x≤1, 0≤y≤1, and 0≤x+y≤1). For example, the semiconductor material of the first semiconductor layer 31 may be one or more selected from among AlGaInN, GaN, AlGaN, InGaN, AlN, and InN doped with an n-type dopant. The n-type dopant doped in the first semiconductor layer 31 may be Si, Ge, Sn, Se, or the like.

The second semiconductor layer 32 is disposed on the first semiconductor layer 31 with the light emitting layer 36 interposed therebetween. The second semiconductor layer 32 may be a p-type semiconductor, and may include a semiconductor material having a chemical formula of AlₓGa_{y}In_{1-x-y}N (0≤x≤1, 0≤y≤1, and 0≤x+y≤1). For example, the semiconductor material of the second semiconductor layer 32 may be one or more selected from among AlGaInN, GaN, AlGaN, InGaN, AlN, and InN doped with a p-type dopant. The p-type dopant doped in the second semiconductor layer 32 may be Mg, Zn, Ca, Ba, or the like.

Accordingly, both ends of the light emitting element ED may have different polarities. Hereinafter, for convenience of explanation, one end to which the second semiconductor layer 32 is adjacent, of both ends of the light emitting element ED will be referred to as a “first end”, and the other end to which the first semiconductor layer 31 is adjacent, of the both ends of the light emitting element ED will be referred to as a “second end”. The first end of the light emitting element ED may be positioned on a side opposite to the second end.

The first end and the second end of the light emitting element ED may have different polarities. In addition, first ends of different light emitting elements ED may have the same polarity, and second ends of the different light emitting elements ED may have the same polarity.

In one or more embodiments, it has been illustrated in FIG. 5 that each of the first semiconductor layer 31 and the second semiconductor layer 32 is configured as one layer, but the present disclosure is not limited thereto. Each of the first semiconductor layer 31 and the second semiconductor layer 32 may further include a larger number of layers, for example, a clad layer or a tensile strain barrier reducing (TSBR) layer, depending on a material of the light emitting layer 36. For example, the light emitting element ED may further include another semiconductor layer disposed between the first semiconductor layer 31 and the light emitting layer 36 or between the second semiconductor layer 32 and the light emitting layer 36. The semiconductor layer disposed between the first semiconductor layer 31 and the light emitting layer 36 may be made of one or more selected from among AlGaInN, GaN, AlGaN, InGaN, AlN, InN, and SLs doped with an n-type dopant, and the semiconductor layer disposed between the second semiconductor layer 32 and the light emitting layer 36 may be made of one or more selected from among AlGaInN, GaN, AlGaN, InGaN, AlN, and InN doped with a p-type dopant.

The light emitting layer 36 may be disposed between the first semiconductor layer 31 and the second semiconductor layer 32. The light emitting layer 36 may include a material having a single or multiple quantum well structure. When the light emitting layer 36 includes the material having the multiple quantum well structure, the light emitting layer 36 may have a structure in which a plurality of quantum layers and well layers are alternately stacked. The light emitting layer 36 may emit light by a combination of electron-hole pairs according to electrical signals applied through the first semiconductor layer 31 and the second semiconductor layer 32. The light emitting layer 36 may include a material such as AlGaN, AlGaInN, or InGaN. In particular, when the light emitting layer 36 has the multiple quantum well structure, that is, the structure in which the quantum layers and the well layers are alternately stacked, the quantum layers may include a material such as AlGaN or AlGaInN, and the well layers may include a material such as GaN or AlInN.

The light emitting layer 36 may have a structure in which semiconductor materials having large band gap energy and semiconductor materials having small band gap energy are alternately stacked, and may include other Group III to Group V semiconductor materials depending on a wavelength band of emitted light. The light emitted by the light emitting layer 36 is not limited to light of a blue wavelength band, and in some cases, the light emitting layer 36 may also emit light of red and green wavelength bands.

The electrode layer 37 may be an ohmic connection electrode. However, the present disclosure is not limited thereto, and the electrode layer 37 may also be a Schottky connection electrode. The light emitting element ED may include at least one electrode layer 37. The light emitting element ED may include one or more electrode layers 37, but the present disclosure is not limited thereto, and the electrode layers 37 may also be omitted.

The electrode layer 37 may decrease resistance between the light emitting element ED and an electrode or a connection electrode when the light emitting element ED is electrically connected to the electrode or the connection electrode in the display device 1. The electrode layer 37 may include a metal having conductivity. The electrode layer 37 may include at least one selected from among aluminum (Al), titanium (Ti), indium (In), gold (Au), silver (Ag), ITO, IZO, and ITZO. Due to the above-described configuration, both ends of each of the light emitting elements ED may have different polarities.

The insulating film 38 is disposed to be around (e.g., to surround) outer surfaces (e.g., outer peripheral or circumferential surfaces) of the plurality of semiconductor layers and the electrode layer described above. For example, the insulating film 38 may be disposed to be around (e.g., to surround) at least an outer surface (e.g., the outer peripheral or circumferential surface) of the light emitting layer 36, but may be formed to expose both ends of the light emitting element ED in a length direction. In addition, the insulating film 38 may also be formed so that an upper surface thereof is rounded in cross section in an area adjacent to at least one end of the light emitting element ED.

The insulating film 38 may include at least one selected from among materials having insulating properties, such as, for example, silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ). It has been illustrated in FIG. 5 that the insulating film 38 is formed as a single layer, but the present disclosure is not limited thereto, and in some embodiments, the insulating film 38 may also be formed in a multilayer structure in which a plurality of layers are stacked.

The insulating film 38 may serve to protect the semiconductor layers and the electrode layer of the light emitting element ED. The insulating film 38 may prevent an electrical short-circuit that may occur in the light emitting layer 36 when the light emitting layer 36 is in direct contact with an electrode through which an electrical signal is transferred to the light emitting element ED. In addition, the insulating film 38 may prevent a decrease in luminous efficiency of the light emitting element ED.

In addition, an outer surface (e.g., an outer peripheral or circumferential surface) of the insulating film 38 may be surface-treated. The light emitting elements ED may be jetted onto and may be aligned on electrodes in a state in which they are dispersed in ink (e.g., a predetermined ink). Here, in order to maintain the light emitting elements ED in a state in which the light emitting elements ED are dispersed without being agglomerated with other adjacent light emitting elements ED in the ink, a hydrophobic or hydrophilic treatment may be performed on a surface of the insulating film 38.

Referring to FIGS. 4 and 6 again, a plurality of light emitting element ED may be disposed on the space between the first alignment electrode RME1 and the second alignment electrode RME2 spaced from each other within the emission area EMA of each sub-pixel SPXn and may be arranged side by side along the second direction DR2.

A hatched portion is illustrated in each of the plurality of light emitting elements ED illustrated in FIG. 6. The hatched portion in each of the plurality of light emitting elements ED may be the light emitting layer 36 illustrated in FIG. 5. One end adjacent to the hatched portion of each of the plurality of light emitting elements ED may be the above-described first end, and an end opposite to the one end may be the second end.

The light emitting elements ED may extend in the first direction DR1 and may be oriented so that the first ends thereof are disposed on one side of the first alignment electrode RME1 in the first direction DR1 and the second ends thereof are disposed on the other side of the second alignment electrode RME2 in the first direction DR1.

The connection electrode CNE may be disposed on the light emitting elements ED. The connection electrode CNE may include a first connection electrode CNE1 and a second connection electrode CNE2 spaced from each other and sequentially arranged toward one side of the first direction DR1.

The first connection electrode CNE1 and the second connection electrode CNE2 may be disposed to be spaced from each other in the first direction DR1. For example, the second connection electrode CNE2 may be disposed on one side of the first connection electrode CNE1 in the first direction DR1.

The first connection electrode CNE1 may be disposed on the first alignment electrode RME1 in the emission area EMA. The first connection electrode CNE1 may have a shape in which it substantially extends in the second direction DR2 in the emission area EMA.

The first connection electrode CNE1 may be in contact with the first ends of the light emitting elements ED in the emission area EMA. For example, the first connection electrode CNE1 may extend in the second direction DR2 in the emission area EMA and may be in contact with the first ends of the light emitting elements ED arranged side by side along the second direction DR2 on the space between the first alignment electrode RME1 and the second alignment electrode RME2 spaced from each other.

The first connection electrode CNE1 may be electrically connected to the first alignment electrode RME1 through a first contact part CT1 in an area that does not overlap the emission area EMA. Accordingly, the first connection electrode CNE1 may receive the above-described first source voltage through the first alignment electrode RME1.

The second connection electrode CNE2 may be disposed on the second alignment electrode RME2 in the emission area EMA. The second connection electrode CNE2 may have a shape in which it substantially extends in the second direction DR2 in the emission area EMA.

The second connection electrode CNE2 may be in contact with the second ends of the light emitting elements ED in the emission area EMA. For example, the second connection electrode CNE2 may extend in the second direction DR2 in the emission area EMA and may be in contact with the second ends of the light emitting elements ED arranged side by side along the second direction DR2 on the space between the first alignment electrode RME1 and the second alignment electrode RME2 spaced from each other.

The second connection electrode CNE2 may be electrically connected to the second alignment electrode RME2 through a second contact part CT2 in an area that does not overlap the emission area EMA. Accordingly, the second connection electrode CNE2 may receive the above-described second source voltage through the second alignment electrode RME2.

Hereinafter, a stacked structure of elements constituting the display device 1 according to one or more embodiments will be described.

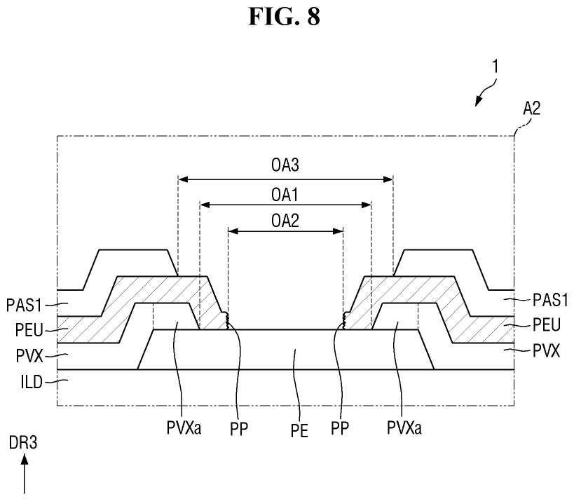

FIG. 7 is a cross-sectional view illustrating a schematic cross section taken along the line X1-X1′ of FIG. 6 and a schematic cross-section of a pad part of the display device according to one or more embodiments. FIG. 8 is an enlarged view of an area A2 of FIG. 7.

A cross-sectional structure of the display device 1 according to one or more embodiments will be described with reference to FIGS. 7 and 8 in conjunction with FIG. 6. The display device 1 may include a substrate SUB, and a semiconductor layer, a plurality of conductive layers, and a plurality of insulating layers disposed on the substrate SUB. In addition, the display device 1 may include the alignment electrode layer RME, the light emitting elements ED, and the connection electrodes CNE, as described above. The semiconductor layer, the conductive layers, and the insulating layers may constitute the circuit element layer CCL of the display device 1, respectively.

The substrate SUB may be made of an insulating material such as glass, quartz, or a polymer resin. In addition, the substrate SUB may be a rigid substrate, but may also be a flexible substrate SUB capable of being bent, folded, or rolled.

The circuit element layer CCL may be disposed on the substrate SUB. In the circuit element layer CCL, various lines transferring electrical signals to the light emitting elements ED disposed on the substrate SUB may be disposed. As illustrated in FIG. 7, the circuit element layer CCL may include a first conductive layer, a semiconductor layer, a second conductive layer, a third conductive layer, and the like, as the plurality of conductive layers and include a buffer layer BL, a first gate insulating layer GI, an interlayer insulating layer ILD, and a passivation layer PVX as the plurality of insulating layers.

The first conductive layer may be disposed on the substrate SUB. The first conductive layer includes a lower metal layer BML, and the lower metal layer BML is disposed to overlap a semiconductor layer ACT1 of the first thin film transistor T1 in the third direction DR3. The lower metal layer BML may prevent light from being incident on the semiconductor layer ACT1 of the first thin film transistor T1 or may be electrically connected to the semiconductor layer ACT1 to serve to stabilize electrical characteristics of the first thin film transistor T1. However, the lower metal layer BML may be omitted.

The buffer layer BL may be disposed on the lower metal layer BML and the substrate SUB. The buffer layer BL may be formed on the substrate SUB in order to protect transistors of the pixel PX from moisture permeating through the substrate SUB vulnerable to moisture permeation, and may perform a surface planarization function.

The semiconductor layer is disposed on the buffer layer BL. The semiconductor layer may include a first semiconductor layer ACT1 of the first thin film transistor T1 and a second semiconductor layer ACT2 of a second thin film transistor T2. The first semiconductor layer ACT1 and the second semiconductor layer ACT2 may be disposed to partially overlap a first gate electrode G1 and a second gate electrode G2 of a second conductive layer to be described later, respectively.

The semiconductor layer may include polycrystalline silicon, single crystal silicon, an oxide semiconductor, or the like. In one or more embodiments, the semiconductor layer may include polycrystalline silicon. The oxide semiconductor may be an oxide semiconductor containing indium (In). For example, the oxide semiconductor may be at least one selected from among indium tin oxide (ITO), indium zinc oxide (IZO), indium gallium oxide (IGO), indium zinc tin oxide (IZTO), indium gallium tin oxide (IGTO), indium gallium zinc oxide (IGZO), and indium gallium zinc tin oxide (IGZTO).

It has been illustrated in FIG. 7 that the first thin film transistor T1 and the second thin film transistor T2 are disposed in the pixel PXn of the display device 1, but the present disclosure is not limited thereto, and the display device 1 may include a larger number of transistors.

The first gate insulating layer GI is disposed on the semiconductor layer in the display area DA. The first gate insulating layer GI may serve as a gate insulating film of each of the transistors T1 and T2. It has been illustrated in FIG. 7 that the first gate insulating layer GI is patterned together with gate electrodes G1 and G2 of a second conductive layer to be described below to be partially disposed between the second conductive layer and the semiconductor layers ACT1 and ACT2 of the semiconductor layer. However, the present disclosure is not limited thereto. In one or more embodiments, the first gate insulating layer GI may be entirely disposed on the buffer layer BL.

The second conductive layer is disposed on the first gate insulating layer GI. The second conductive layer may include the first gate electrode G1 of the first thin film transistor T1 and the second gate electrode G2 of the second thin film transistor T2. The first gate electrode G1 may be disposed to overlap a channel region of the first semiconductor layer ACT1 in the third direction DR3, which is the thickness direction, and the second gate electrode G2 may be disposed to overlap a channel region of the second semiconductor layer ACT2 in the third direction DR3, which is the thickness direction.

The interlayer insulating layer ILD is disposed on the second conductive layer. The interlayer insulating layer ILD may function as an insulating film between the second conductive layer and other layers disposed on the second conductive layer, and protect the second conductive layer.

The third conductive layer is disposed on the interlayer insulating layer ILD. The third conductive layer may include a metal. In one or more embodiments, the third conductive layer may include one or more metals selected from the group consisting of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), and copper (Cu), but is not limited thereto. For convenience of explanation, it will hereinafter be mainly described that the third conductive layer includes copper (Cu).

The third conductive layer may include a first voltage line VL1 and a second voltage line VL2, a first conductive pattern CDP1, and source electrodes S1 and S2 and drain electrodes D1 and D2 of the respective transistors T1 and T2 disposed in the display area DA and a pad electrode PE disposed in the pad area PDA.

The high potential voltage (or the first source voltage) transferred to the first alignment electrode RME1 may be applied to the first voltage line VL1, and the low potential voltage (or the second source voltage) transferred to the second alignment electrode RME2 may be applied to the second voltage line VL2. A portion of the first voltage line VL1 may be in contact with the first semiconductor layer ACT1 of the first thin film transistor T1 through a contact hole penetrating through the interlayer insulating layer ILD. The first voltage line VL1 may serve as a first drain electrode D1 of the first thin film transistor T1. The first voltage line VL1 may be directly connected to the first alignment electrode RME1, and the second voltage line VL2 may be directly connected to the second alignment electrode RME2.

The first conductive pattern CDP1 may be in contact with the first semiconductor layer ACT1 of the first thin film transistor T1 through a contact hole penetrating through the interlayer insulating layer ILD. The first conductive pattern CDP1 may be in contact with the lower metal layer BML through another contact hole penetrating through the interlayer insulating layer ILD and the buffer layer BL. The first conductive pattern CDP1 may serve as a first source electrode S1 of the first thin film transistor T1. In addition, the first conductive pattern CDP1 may be connected to a first alignment electrode RME1 or a first connection electrode CNE1 to be described later. The first thin film transistor T1 may transfer the first source voltage applied from the first voltage line VL1 to the first alignment electrode RME1 or the first connection electrode CNE1.

A second source electrode S2 and a second drain electrode D2 may be in contact with the second semiconductor layer ACT2 of the second thin film transistor T2 through contact holes penetrating through the interlayer insulating layer IL, respectively.

The pad electrode PE may be disposed on the interlay insulating layer ILD in the pad area PDA. The pad electrode PE may be a pad electrode of the wiring pad WPD described with reference to FIG. 2. For example, the pad electrode PE may be a pad electrode constituting the scan wiring pad WPD_SC, the data wiring pad WPD_DT, the initialization wiring pad WPD_Vint, the first voltage wiring pad WPD_VL1, or the second voltage wiring pad WPD_VL2. The pad electrode PE may be electrically connected to the external device through an anisotropic conductive film, ultrasonic bonding, or the like.

In one or more embodiments, it has been illustrated in FIGS. 7 and 8 that the pad electrode PE is included in the third conductive layer, but the present disclosure is not limited thereto. For example, the pad electrode PE may also be included in the first conductive layer or the second conductive layer. When the pad electrode PE is included in the first conductive layer or the second conductive layer, the interlayer insulating layer ILD may be removed in the pad area PDA.

The passivation layer PVX is disposed on the third conductive layer. The passivation layer PVX may function as an insulating film between the third conductive layer and other layers and protect the third conductive layer.

The passivation layer PVX may include openings exposing the first conductive pattern CDP1, the second voltage line VL2, and the pad electrode PE. For example, the passivation layer PVX may include the first electrode contact hole CTD exposing the first conductive pattern CDP1, the second electrode contact hole CTS exposing the second voltage line VL2, and a first opening OA1 exposing the pad electrode PE as illustrated in FIG. 8.

In the pad area PDA, the passivation layer PVX may cover a portion of an upper surface and side surfaces of the pad electrode PE. The passivation layer PVX may be disposed on the interlayer insulating layer ILD in the pad area PDA, and may extend to cover the side surfaces of the pad electrode PE and then extend to cover a portion of the upper surface of the pad electrode PE. The passivation layer PVX may include an overlapping part PVXa disposed on the upper surface of the pad electrode PE in the pad area PDA. The overlapping part PVXa may be disposed on the upper surface of the pad electrode PE to form the first opening OA1 exposing a portion of the upper surface of the pad electrode PE.

Due to the above-described configuration, the passivation layer PVX may prevent the side surfaces of the pad electrode PE disposed in the pad area PDA from being corroded in manufacturing processes of a display device to be described later, and may maintain a state in which the pad electrode PE is electrically insulated from lines disposed adjacent to the pad electrode PE.

Each of the buffer layer BL, the first gate insulating layer GI, the interlayer insulating layer ILD, and the passivation layer PVX described above may be formed as a plurality of inorganic layers that are alternately stacked. For example, each of the buffer layer BL, the first gate insulating layer GI, the interlayer insulating layer ILD, and the passivation layer PVX may be formed as a double layer in which inorganic layers including at least one selected from among silicon oxide (SiOₓ), silicon nitride (SiNₓ), and silicon oxynitride (SiOₓN_{y}) are stacked or a multiple layer in which these layers are alternately stacked.

A via insulating layer VIA may be disposed on the circuit element layer CCL in the display area DA. In detail, the via insulating layer VIA may be disposed on the passivation layer PVX of the circuit element layer CCL in the display area DA, but may not be disposed on the pad area PDA. Accordingly, the via insulating layer VIA may cover the first thin film transistor T1 and the second thin film transistor T2 in the display area DA, but may not cover the pad electrode PE in the pad area PDA.

The via insulating layer VIA may include an organic insulating material, for example, an organic insulating material such as polyimide (PI) to compensate for a step due to several lines inside the circuit element layer and make an upper surface flat.

The internal banks BP is disposed on an upper surface of the via insulating layer VIA in the display area DA. In other words, the via insulating layer VIA and the internal banks BP may be in direct contact with each other.

The internal banks BP may be disposed on the via insulating layer VIA. The internal banks BP may have side surfaces inclined or curved with a suitable curvature (e.g., a predetermined curvature), and light emitted from the light emitting elements ED may be reflected from the alignment electrodes RME1 and RME2 disposed on the internal banks BP to be emitted toward one side in the third direction DR3. The internal banks BP may include a transparent organic insulating material such as polyimide, but are not limited thereto. For example, the internal banks BP may further include a colored dye such as a black pigment.

The alignment electrode layer RME may be disposed on the via insulating layer VIA and the internal banks BP in the display area DA, and may be disposed on the pad electrode PE in the pad area PDA. For example, the alignment electrode layer RME may include the first alignment electrode RME1 disposed on the first internal bank BP1 in the display area DA, the second alignment electrode RME2 disposed on the second internal bank BP2 in the display area DA, and a pad upper electrode PEU disposed on the passivation layer PVX and the pad electrode PE in the pad area PDA and including a second opening OA2 exposing the upper surface of the pad electrode PE.

The first alignment electrode RME1 may be disposed on the via insulating layer VIA, overlap the first internal bank BP1 in the third direction DR3, and extend in a direction toward the second internal bank BP2. The second alignment electrode RME2 may be disposed on the via insulating layer VIA, overlap the second internal bank BP2 in the third direction DR3, and extend in a direction toward the first internal bank BP1.

An interval between the first and second alignment electrodes RME1 and RME2 that are spaced from each other may be smaller than an interval between the first and second internal banks BP1 and BP2 that are spaced apart from each other. Accordingly, the first alignment electrode RME1 and the second alignment electrode RME2 may extend from a space between the first internal bank BP1 and the second internal bank BP2 that are spaced from each other to portions in direct contact with the via insulating layer VIA.

The first alignment electrode RME1 may be in contact with the first conductive pattern CDP1 through the first electrode contact hole CTD penetrating through the via insulating layer VIA, and the passivation layer PVX. The second alignment electrode RME2 may be in contact with the second voltage line VL2 through the second electrode contact hole CTS penetrating through the via insulating layer VIA, and the passivation layer PVX.

The pad upper electrode PEU may be disposed on the passivation layer PVX in the pad area PDA. The pad upper electrode PEU may cover the overlapping part PVXa of the passivation layer PVX. In one or more embodiments, the pad upper electrode PEU may cover a side surface of the overlapping part PVXa beyond an upper surface of the overlapping part PVXa, and may be in contact with a portion of the upper surface of the pad electrode PE exposed by the first opening OA1.

The pad upper electrode PEU may include the second opening OA2 exposing the upper surface of the pad electrode PE. Because the pad upper electrode PEU is disposed up to a portion of the upper surface of the pad electrode PE exposed by the first opening OA1 beyond the overlapping part PVXa, a width of the second opening OA2 may be smaller than a width of the first opening OA1.

A peeling pattern PP having an irregular shape may be formed at one end of the pad upper electrode PEU constituting the second opening OA2. The reason why the peeling pattern PP has the irregular shape may be that the peeling pattern PP is formed by mechanical peeling of the pad upper electrode PEU in manufacturing processes of a display device. A description thereof will be provided later.

The alignment electrode layer RME may include a conductive material having high reflectivity. For example, the alignment electrode layer RME may include a metal such as silver (Ag), copper (Cu), or aluminum (Al), include an alloy including aluminum (Al), nickel (Ni), lanthanum (La), or the like, or have a structure in which a metal layer made of titanium (Ti), molybdenum (Mo), and niobium (Nb) and the alloy are stacked.

In one or more embodiments, the alignment electrode layer RME may be formed as a double layer or a multiple layer in which an alloy including aluminum (Al) and one or more metal layers made of titanium (Ti), molybdenum (Mo), and niobium (Nb) are stacked. Hereinafter, it will be mainly described that the alignment electrode layer RME includes aluminum (Al).

The first insulating layer PAS1 may be disposed over the entirety of the display area DA, and may be disposed on the alignment electrode layers RME. The first insulating layer PAS1 may include an insulating material to insulate different electrodes constituting the alignment electrode layer RME from each other while protecting the alignment electrode layer RME. In addition, the first insulating layer PAS1 may prevent the light emitting elements ED disposed on the first insulating layer PAS1 from being in direct contact with and being damaged by other members.

In one or more embodiments, the first insulating layer PAS1 may have a step formed so that a portion of an upper surface thereof is recessed in the space between the alignment electrodes RME1 and RME2 that are spaced from each other. The light emitting elements ED may be disposed on the upper surface of the first insulating layer PAS1 in which the step is formed, and spaces may be formed between the light emitting elements ED and the first insulating layer PAS1.

The first insulating layer PAS1 may include contact parts CT1 and CT2 in the display area DA. The contact parts may be disposed to overlap different alignment electrodes RME1 and RME2, respectively. For example, the contact parts may include a first contact part CT1 disposed to overlap the first alignment electrode RME1 and a second contact part CT2 disposed to overlap the second alignment electrode RME2.

In the display area DA, the first contact part CT1 and the second contact part CT2 may penetrate through the first insulating layer PAS1 to expose, respectively, portions of upper surfaces of the first alignment electrode RME1 and the second alignment electrode RME2 disposed below the first insulating layer PAS1. The first contact part CT1 and the second contact part CT2 may further penetrate through portions of the other insulating layers disposed on the first insulating layer PAS1, respectively. The alignment electrodes RME1 and RME2 exposed by the respective contact parts may be in contact with the connection electrodes CNE. The light emitting elements ED may be in contact with the connection electrodes CNE to be electrically connected to the alignment electrodes RME1 and RME2 and the circuit element layer CCL disposed below the via insulating layer VIA, and accordingly, may receive electric signals applied thereto to emit light of a specific wavelength band.

The first insulating layer PAS1 may include a third opening OA3 exposing the upper surface of the pad electrode PE exposed by the second opening OA2 in the pad area PDA, as illustrated in FIG. 8. In one or more embodiments, the third opening OA3 formed in the first insulating layer PAS1 may have a width smaller than that of the pad electrode PE and have a width greater than those of the first opening OA1 and the second opening OA2, but is not limited thereto.

The external bank BNL may be disposed on the first insulating layer PAS1. The external bank BNL may include portions extending in the first direction DR1 and the second direction DR2, and surround the respective sub-pixels SPXn. The external bank BNL may divide the respective sub-pixels SPXn while surrounding the respective sub-pixels SPXn, and may divide the display area DA and the non-display area NDA while surrounding the outermost portion of the display area DA.

The external bank BNL may have a suitable height (e.g., a predetermined height), similar to the internal bank BP. In one or more embodiments, an upper surface of the external bank BNL may be higher than that of the internal bank BP, and a thickness of the external bank BNL may be equal to or greater than that of the internal bank BP. Accordingly, the external bank BNL may effectively prevent ink from overflowing into adjacent sub-pixels SPXn in an inkjet printing process of manufacturing processes of the display device 1. The external bank BNL may include a transparent organic insulating material made of such as polyimide like the internal bank BP, but is not limited thereto. For example, the external bank BNL may include a colored dye such as a black pigment.

A second insulating layer PAS2 may be disposed on the plurality of light emitting elements ED, the first insulating layer PAS1, and the external bank BNL. The second insulating layer PAS2 includes pattern parts extending in the first direction DR1 between the internal banks BP and disposed on the plurality of light emitting elements ED. The pattern parts may be disposed to partially surround outer surfaces (e.g., outer peripheral or circumferential surfaces) of the light emitting elements ED, and may not cover both sides or both ends of the light emitting elements ED. The pattern parts may form a linear or island-shaped pattern in each sub-pixel SPXn in a plan view. The pattern parts of the second insulating layer PAS2 may fix the light emitting elements ED in the manufacturing processes of the display device 1 while protecting the light emitting elements ED. In addition, the second insulating layer PAS2 may be disposed to fill spaces between the light emitting elements ED and the first insulating layer PAS1 below the light emitting elements ED.

The second insulating layer PAS2 may include contact parts CT1 and CT2 in the display area DA. The contact parts may be disposed to overlap different alignment electrode layers RME, respectively. For example, the contact parts may include a first contact part CT1 disposed to overlap the first alignment electrode RME1 and a second contact part CT2 disposed to overlap the second alignment electrode RME2. The first contact part CT1 and the second contact part CT2 may penetrate through the second insulating layer PAS2 to expose, respectively, portions of the upper surfaces of the first alignment electrode RME1 and the second alignment electrode RME2 disposed below the second insulating layer PAS2. The first contact part CT1 and the second contact part CT2 may further penetrate through portions of the other insulating layers disposed on the second insulating layer PAS2, respectively. The alignment electrode layers RME exposed by the respective contact parts may be in contact with the connection electrodes CNE. The light emitting elements ED may be in contact with the connection electrodes CNE to be electrically connected to the alignment electrode layers RME and the circuit element layer CCL disposed below the via insulating layer VIA, and accordingly, may receive electric signals applied thereto to emit light of a specific wavelength band.

The second insulating layer PAS2 may not be disposed in the pad area PDA. For example, the second insulating layer PAS2 may be removed in the pad area PDA through a separate process. Accordingly, the upper surface of the pad electrode PE may be exposed to the outside through the third opening OA3 formed in the first insulating layer PAS1 to be connected to the external device.

The first connection electrode CNE1 of the connection electrode CNE may be disposed on the second insulating layer PAS2. The first connection electrode CNE1 may partially overlap the first alignment electrode RME1 in the emission area EMA, and may be in contact with the first ends of the light emitting elements ED.

The first connection electrode CNE1 may be disposed from the emission area EMA beyond the external bank BNL as illustrated in FIG. 7. The first connection electrode CNE1 may be in contact with the first alignment electrode RME1 through the first contact part CT1 penetrating through the first insulating layer PAS1 and the second insulating layer PAS2. Accordingly, the first connection electrode CNE1 may be electrically connected to the first thin film transistor T1 to receive the first source voltage applied thereto.

A third insulating layer PAS3 may be disposed on the second insulating layer PAS2, the first connection electrode CNE1, and the external bank BNL. The third insulating layer PAS3 may not cover one ends of the light emitting elements ED. In other words, the third insulating layer PAS3 may not cover the second ends of the light emitting elements ED with which the first connection electrode CNE1 is not in contact in the emission area EMA.

The third insulating layer PAS3 may include the second contact part CT2 disposed to overlap the second alignment electrode RME2. The second contact part CT2 may penetrate through the third insulating layer PAS3 to expose a portion of the upper surface of the second alignment electrode RME2 disposed below the third insulating layer PAS3.

The second alignment electrode RME2 exposed by the second contact part CT2 may be in contact with the second connection electrode CNE2. Accordingly, the light emitting elements ED may be in contact with the connection electrodes CNE to be electrically connected to the alignment electrode layers RME and the circuit element layer CCL disposed below the via insulating layer VIA, and may receive electric signals applied thereto to emit light of a specific wavelength band.

The third insulating layer PAS3 may not be disposed in the pad area PDA. For example, the third insulating layer PAS3 may be removed in the pad area PDA through a separate process. Accordingly, the upper surface of the pad electrode PE may be exposed to the outside through the third opening OA3 formed in the first insulating layer PAS1 to be connected to the external device.

The second connection electrode CNE2 of the connection electrode CNE may be disposed on the third insulating layer PAS3. The second connection electrode CNE2 may partially overlap the second alignment electrode RME2 in the emission area EMA, and may be in contact with the second ends of the light emitting elements ED.

The second connection electrode CNE2 may be disposed from the emission area EMA beyond the external bank BNL as illustrated in FIG. 7. The second connection electrode CNE2 may be in contact with the second alignment electrode RME2 through the second contact part CT2 penetrating through the first insulating layer PAS1, the second insulating layer PAS2, and the third insulating layer PAS3. Accordingly, the second connection electrode CNE2 may be electrically connected to the second power line VL2 to receive the second source voltage applied thereto.

The connection electrodes CNE may include a conductive material. For example, the first and second connection electrodes CNE1 and CNE2 may include ITO, IZO, ITZO, aluminum (Al), and/or the like. As an example, the connection electrodes CNE may include a transparent conductive material, and the light emitted from the light emitting elements ED may be transmitted through the connection electrodes CNE and then emitted.

Each of the first insulating layer PAS1, the second insulating layer PAS2, and the third insulating layer PAS3 described above may include an inorganic insulating material or an organic insulating material. In one or more embodiments, each of the first insulating layer PAS1, the second insulating layer PAS2, and the third insulating layer PAS3 may be made of one or more selected from among silicon oxide (SiOₓ), silicon nitride (SiNₓ), and silicon oxynitride (SiOₓN_{y}). All of the first insulating layer PAS1, the second insulating layer PAS2, and the third insulating layer PAS3 may be made of the same material, some of the first insulating layer PAS1, the second insulating layer PAS2, and the third insulating layer PAS3 may be made of the same material and the others thereof may be made of a different material, or all of the first insulating layer PAS1, the second insulating layer PAS2, and the third insulating layer PAS3 may be made of different materials.

Hereinafter, manufacturing processes of the display device 1 according to one or more embodiments will be described.

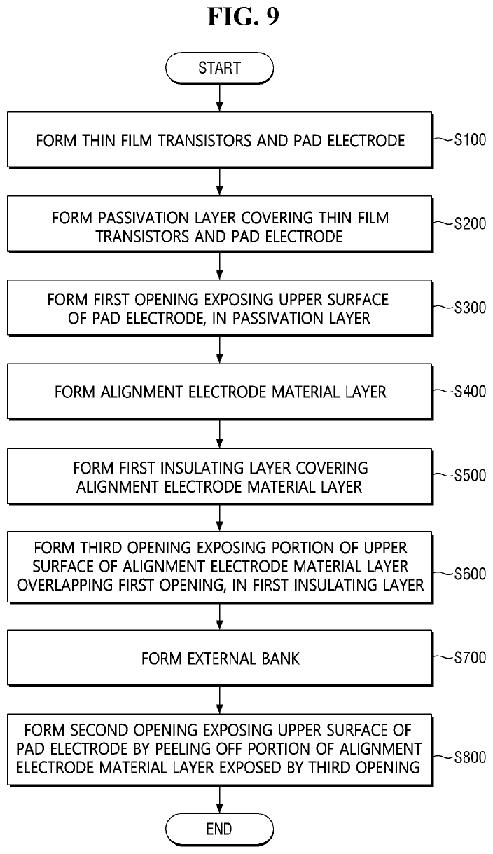

FIGS. 9 to 17 are a flowchart and cross-sectional views for describing a manufacturing process of a display device according to one or more embodiments.

Referring to FIGS. 9 to 17, the manufacturing process of the display device 1 according to one or more embodiments may include forming thin film transistors T1 and T2 and a pad electrode PE (S100); forming a passivation layer PVX covering the thin film transistors T1 and T2 and the pad electrode PE (S200); forming a first opening OA1 exposing an upper surface of the pad electrode PE, in the passivation layer PVX (S300); forming an alignment electrode material layer RME′ (S400); forming a first insulating layer PAS1 covering the alignment electrode material layer RME′ (S500); forming a third opening OA3 exposing a portion of an upper surface of the alignment electrode material layer RME′ overlapping the first opening OA1, in the first insulating layer PAS1 (S600); forming an external bank BNL (S700), and forming a second opening OA2 exposing the upper surface of the pad electrode PE by peeling off a portion of the alignment electrode material layer RME′ exposed by the third opening OA3 (S800).

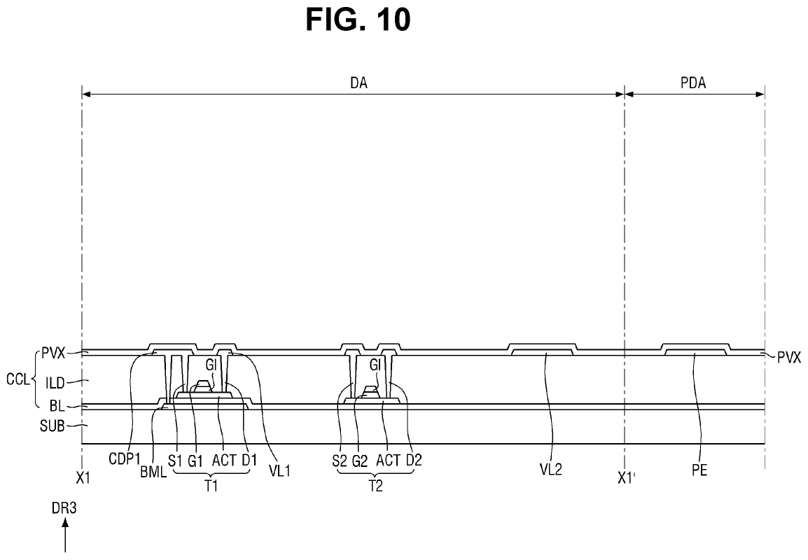

First, referring to FIG. 10 in conjunction with FIG. 7, the circuit element layer CCL including the thin film transistors T1 and T2 disposed in the display area DA, the pad electrode PE disposed on the pad area PDA, and the passivation layer PVX covering the thin film transistors T1 and T2 and the pad electrode PE is formed on the substrate SUB in which the display area DA and the pad area PDA are defined (S100 and S200).

A process of forming the circuit element layer CCL may be performed, for example, by sequentially forming the first conductive layer including a lower metal layer BML, the buffer layer BL, the second conductive layer including the semiconductor layers ACT1 and ACT2, the gate insulating layer GI, and the gate electrodes G1 and G2, the interlayer insulating layer ILD, and the third conductive layer including the source electrodes S1 and S2, the drain electrodes D1 and D2, the first conductive pattern CDP1, the first voltage line VL1, the second voltage line VL2, and the pad electrode PE on the substrate SUB.

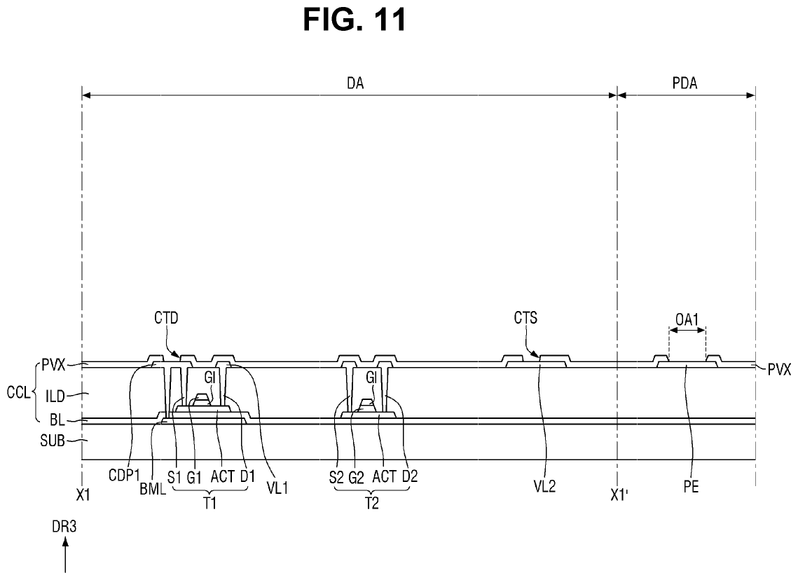

Then, referring to FIG. 11 in conjunction with FIG. 7, the first electrode contact hole CTD exposing the first conductive pattern CDP1 and the second electrode contact hole CTS exposing the second voltage line VL2 in the display area DA and the first opening OA1 exposing the pad electrode PE in the pad area PDA are formed in the passivation layer PVX covering the thin film transistors T1 and T2 and the pad electrode PE (S300).

A process of forming the first electrode contact hole CTD, the second electrode contact hole CTS, and the first opening OA1 may be performed through dry etching using a photoresist pattern as an etch stop layer.

A width of the first opening OA1 may be smaller than a width of the pad electrode PE. In other words, in the pad area PDA, the passivation layer PVX may be disposed to surround the side surfaces of the pad electrode PE, and may expose a portion of the upper surface of the pad electrode PE through the first opening OA1.

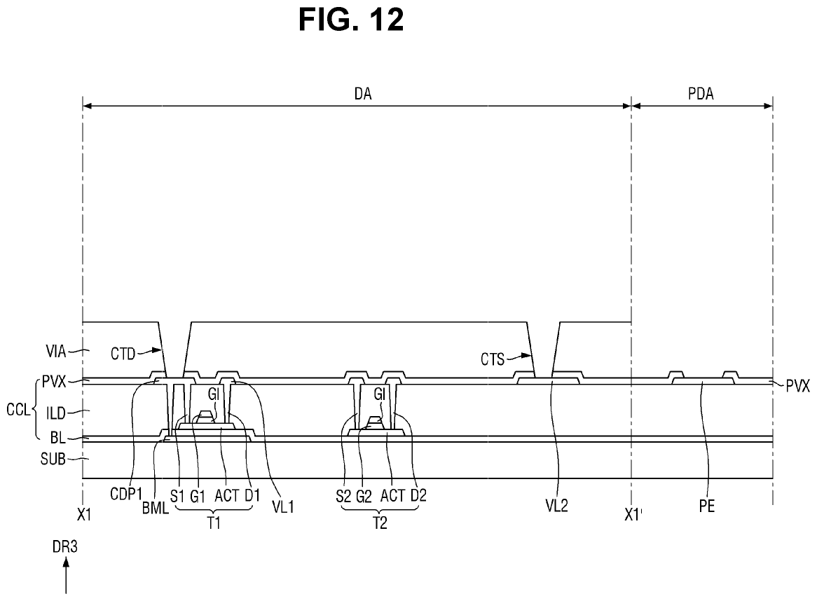

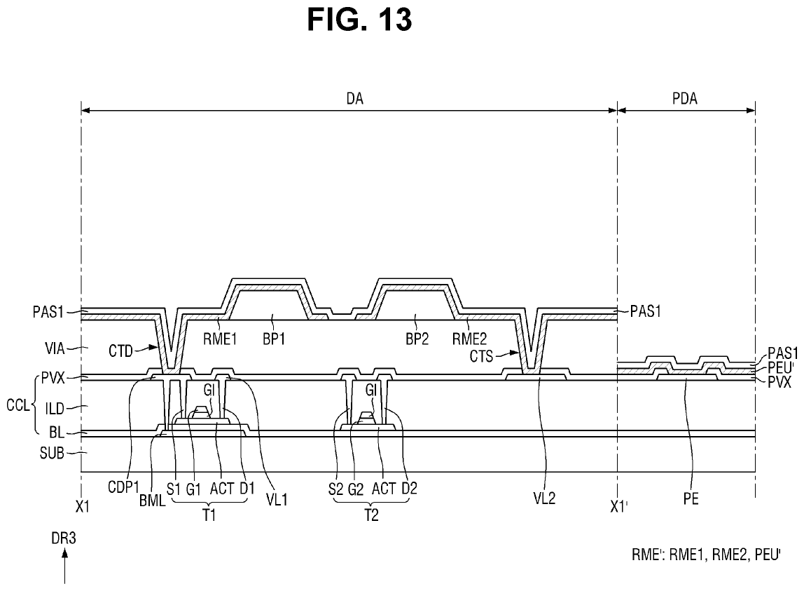

Then, referring to FIGS. 12 and 13 in conjunction with FIG. 7, the via insulating layer VIA that is disposed on the thin film transistors T1 and T2 of the circuit element layer CCL in the display area DA and is not disposed on the pad area PDA is formed, the internal banks BP: BP1 and BP2 are formed on the via insulating layer VIA, and the alignment electrode material layer RME′ and the first insulating layer PAS1 are sequentially formed (S400 and S500).

The via insulating layer VIA may compensate for a step generated by various elements of the circuit element layer CCL in the display area DA, and include the first electrode contact hole CTD exposing the first conductive pattern CDP1 and the second electrode contact hole CTS exposing the second voltage line VL2.

The alignment electrode material layer RME′ may include the first alignment electrode RME1 and the second alignment electrode RME2 disposed on the first internal bank BP1 and the second internal bank BP2, respectively, so as to be spaced from each other in the display area DA and a pad upper electrode material layer PEU′ entirely covering the upper surface of the pad electrode PE exposed by the first opening OA1 (see FIG. 11) of the passivation layer PVX in the pad area PDA.

The first insulating layer PAS1 may cover the alignment electrode material layer RME′ and a portion of the via insulating layer VIA exposed by the alignment electrode material layer RME′ in the display area DA, and cover the pad upper electrode material layer PEU′ in the pad area PDA.

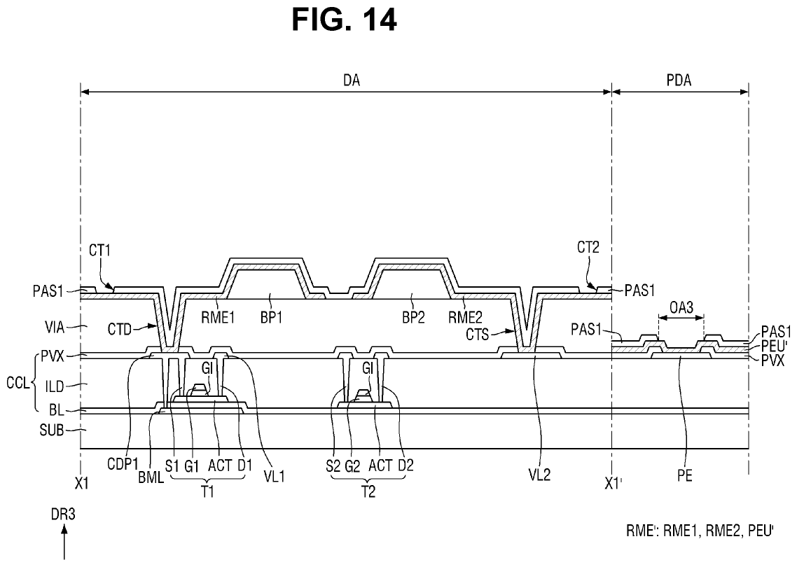

Then, referring to FIG. 14 in conjunction with FIG. 7, the first contact part CT1 exposing a portion of the first alignment electrode RME1 and the second contact part CT2 exposing a portion of the second alignment electrode RME2 in the display area DA and the third opening OA3 exposing a portion of the pad upper electrode material layer PEU′ in the pad area PDA are formed in the first insulating layer PAS1 (S600).

A process of forming the first contact part CT1, the second contact part CT2, and the third opening OA3 may be performed through dry etching using a photoresist pattern as an etch stop layer.

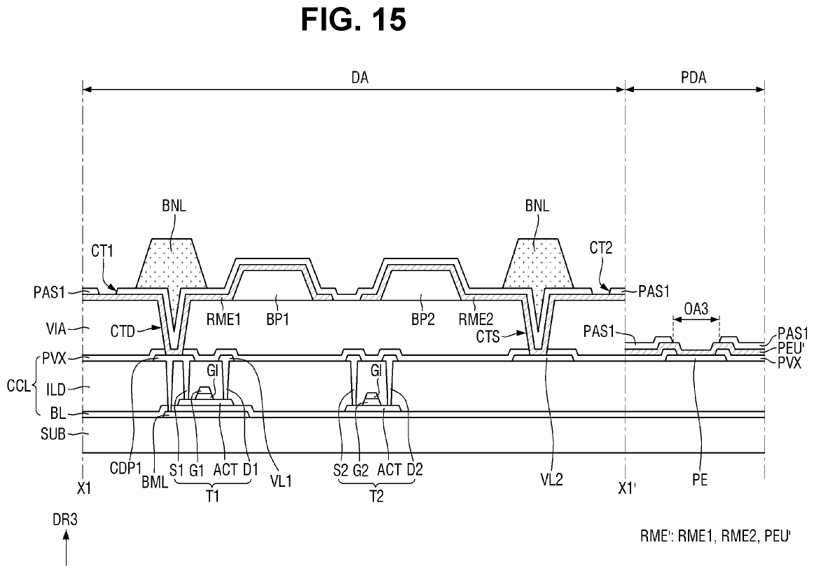

Then, referring to FIG. 15 in conjunction with FIG. 7, the external bank BNL is formed on the first insulating layer PAS1 in the display area DA. A process of forming the external bank BNL may be performed by forming an organic layer including a photosensitive organic material and then exposing and developing the organic layer. In this case, potassium hydroxide (KOH) may be used as a developer.

When the external bank BNL is formed using potassium hydroxide (KOH) as the developer, the pad electrode PE and the pad upper electrode material layer PEU′ may be spaced from each other at an interface between the pad electrode PE and the pad upper electrode material layer PEU′ disposed in the pad area PDA. In this case, when the external device is mounted on the pad area PDA in the presence of the pad upper electrode material layer PEU′, the external device and the pad electrode PE may not be properly connected to each other, which may cause a connection failure. Accordingly, the above-described connection failure may be prevented or at least alleviated by mechanically peeling off the pad upper electrode material layer PEU′ spaced from the pad electrode PE to expose the pad electrode PE and directly connecting the pad electrode PE and the external device to each other.

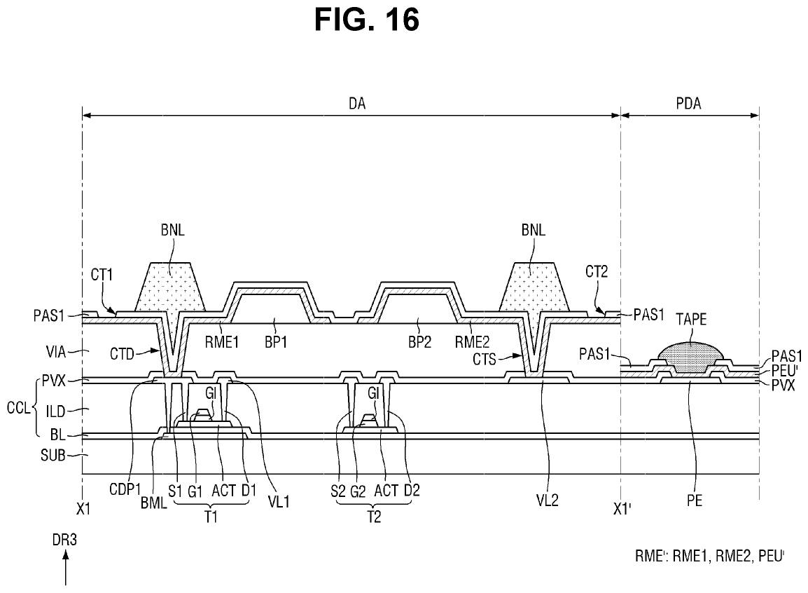

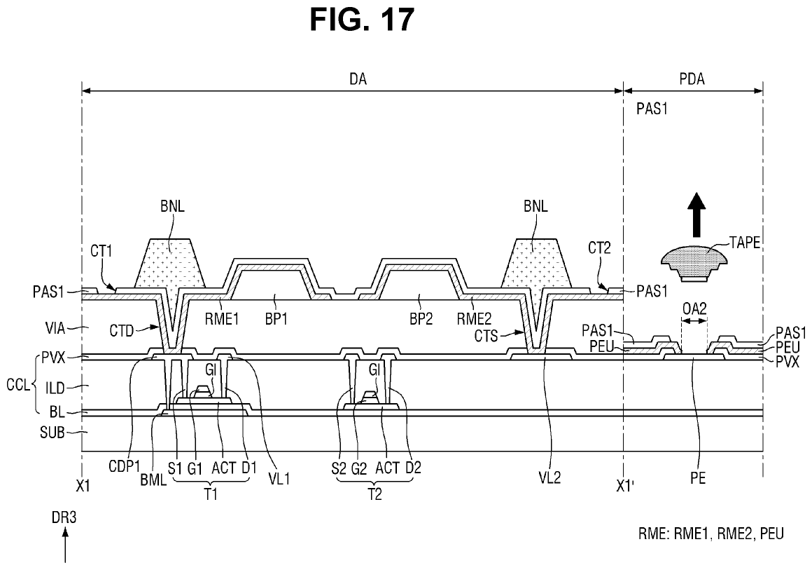

Then, referring to FIGS. 16 and 17, the second opening OA2 exposing the upper surface of the pad electrode PE is formed by peeling off a portion of the pad upper electrode material layer PEU′ exposed by the third opening OA3 (see FIG. 15).

A process of peeling off a portion of the pad upper electrode material layer PEU′ may be performed by mechanical peeling using a tape TAPE. As described above, the pad electrode PE and the pad upper electrode material layer PEU′ are spaced from each other at the interface between the pad electrode PE and the pad upper electrode material layer PEU by the developer while forming the external bank BNL, and thus, an adhesive force between the pad electrode PE and the pad upper electrode material layer PEU′ may become relatively small. For example, an adhesive force between the pad upper electrode material layer PEU′ and the passivation layer PVX may be greater than the adhesive force between the pad electrode PE and the pad upper electrode material layer PEU′.

Accordingly, when the tape TAPE is adhered onto a portion of the pad upper electrode material layer PEU′ exposed by the third opening OA3 and is then lifted, a portion of the pad upper pad electrode material layer PEU′ of which an adhesive force is relatively small may be peeled off. In other words, a portion of the pad upper electrode material layer PEU′ overlapping the pad electrode PE in the third direction DR3 is peeled off, such that the pad upper electrode PEU including the second opening OA2 exposing the upper surface of the pad electrode PE may be formed. In this case, a portion of the pad upper electrode material layer PEU′ is mechanically peeled off, and thus, the peeling pattern PP as illustrated in FIG. 8 may be formed.

Then, the display device 1 according to one or more embodiments is manufactured by aligning the light emitting elements ED (see FIG. 7) and then sequentially forming the second insulating layer PAS2, the first connection electrode CNE1, the third insulating layer PAS3, and the second connection electrode CNE2. The second insulating layer PAS2 and the third insulating layer PAS3 may be removed in the pad area PDA.

Connectivity between the pad electrode PE and the external device in the pad area PDA of the display device 1 is improved by the configuration and the manufacturing method as described above, and thus, device reliability of the pad part may be improved.

Hereinafter, other embodiments of the display device 1 will be described. In the following embodiments, the same components as those of the above-described embodiment will be denoted by the same reference numerals, and an overlapping description thereof will be omitted or simplified and contents different from those described above will be mainly described.

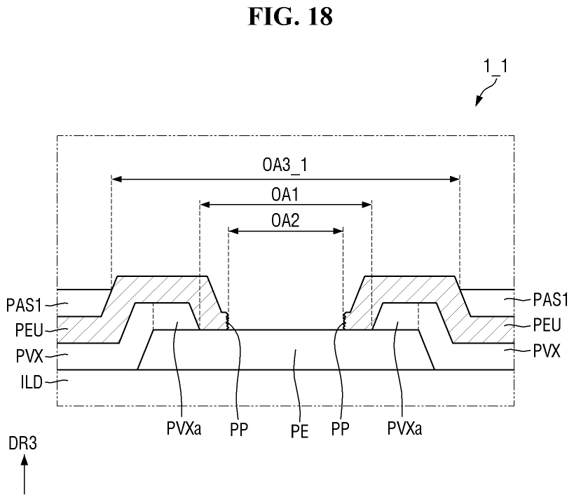

FIG. 18 is a cross-sectional view illustrating a structure of a pad part of a display device according to one or more embodiments.

Referring to FIG. 18, it is illustrated that a third opening OA3_1 of a display device 1_1 according to the present embodiment may completely expose a portion of the pad upper electrode PEU covering the upper surface of the overlapping part PVXa.

For example, the first insulating layer PAS1 of the display device 1_1 according to the present embodiment may not be disposed on a portion of the pad upper electrode PEU covering the upper surface of the overlapping part PVXa. Accordingly, an interval between the pad electrode PE and an external device connected to the pad electrode PE is decreased by a thickness of the first insulating layer PAS1, and thus, connectivity between the pad electrode PE and the external device may be improved.

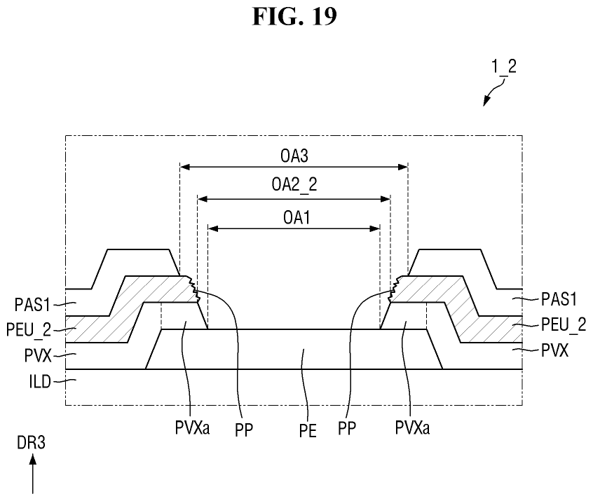

FIG. 19 is a cross-sectional view illustrating a structure of a pad part of a display device according to one or more embodiments.

Referring to FIG. 19, it is illustrated that a pad upper electrode PEU_2 of a display device 1_2 according to the present embodiment is not disposed on the side surface of the overlapping part PVXa of the passivation layer PVX, but may be disposed only on the upper surface of the overlapping part PVXa.

For example, a width of a second opening OA_2 formed by the pad upper electrode PEU_2 may be greater than that of the first opening OA1 and smaller than that of the third opening OA3. Accordingly, an exposed area of the pad electrode PE is increased, and thus, connectivity between the pad electrode PE and an external device mounted on the pad electrode PE may be improved.

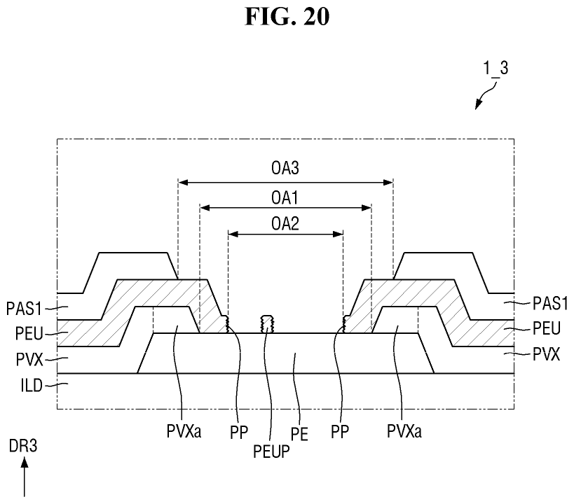

FIG. 20 is a cross-sectional view illustrating a structure of a pad part of a display device according to one or more embodiments.

Referring to FIG. 20, it is illustrated that in a display device 1_3 according to the present embodiment, a pad upper electrode pattern PEUP may be disposed on the upper surface of the pad electrode PE exposed by the second opening OA2.

The pad upper electrode pattern PEUP may be a residue of the pad upper electrode material layer PEU′ (see FIG. 16) remaining without being peeled off in the manufacturing processes of a display device described above. In other words, the pad upper electrode pattern PEUP is a portion of the pad upper electrode material layer PEU′ and may be a portion that is not spaced from the interface of the pad electrode PE by the developer used to form the external bank BNL.

In concluding the detailed description, those skilled in the art will appreciate that many variations and modifications can be made to the disclosed embodiments without substantially departing from the principles and scope of the present disclosure. Therefore, the embodiments of the present disclosure are used in a generic and descriptive sense only and not for purposes of limitation.

What is claimed is:

1. A display device comprising:
a substrate including a display area and a pad area;
a circuit element layer on the substrate; and
an alignment electrode layer on the circuit element layer,
wherein the circuit element layer comprises:
a thin film transistor in the display area; and
a pad electrode in the pad area,
wherein the alignment electrode layer comprises:
a first alignment electrode and a second alignment electrode spaced from each other in the display area; and
a pad upper electrode including a first opening exposing the pad electrode in the pad area, and
wherein a light emitting element is located in a space between the first alignment electrode and the second alignment electrode that are spaced from each other.

2. The display device of claim 1, further comprising a passivation layer between the circuit element layer and the alignment electrode layer,
wherein the passivation layer includes a second opening exposing the pad electrode.

3. The display device of claim 2, wherein the passivation layer comprises an overlapping part on an upper surface of the pad electrode and forming the second opening, and
wherein the pad upper electrode covers a portion of the upper surface of the pad electrode exposed by the second opening beyond the overlapping part.

4. The display device of claim 3, wherein a width of the first opening is smaller than a width of the second opening.

5. The display device of claim 4, wherein the pad upper electrode comprises a peeling cross section of an irregular pattern at a portion forming the first opening, and
wherein the peeling cross section overlaps the upper surface of the pad electrode exposed by the second opening.

6. The display device of claim 5, wherein an adhesive force between the pad upper electrode and the pad electrode is smaller than an adhesive force between the pad upper electrode and the overlapping part.

7. The display device of claim 6, wherein the pad upper electrode comprises aluminum (Al), and
wherein the pad electrode comprises copper (Cu).

8. The display device of claim 2, wherein the passivation layer comprises an overlapping part on an upper surface of the pad electrode and forming the second opening, and
wherein the pad upper electrode covers a portion of an upper surface of the overlapping part.

9. The display device of claim 8, wherein a width of the first opening is smaller than a width of the second opening.

10. The display device of claim 9, wherein the pad upper electrode comprises a peeling cross section of an irregular pattern at a portion forming the first opening, and
wherein the peeling cross section overlaps the overlapping part.

11. The display device of claim 2, further comprising a first insulating layer on the alignment electrode layer,
wherein the first insulating layer comprises a third opening exposing the pad electrode.

12. The display device of claim 11, further comprising an external bank on the first insulating layer and defining an emission area in which the light emitting element is located.

13. The display device of claim 1, wherein the thin film transistor comprises:
a semiconductor layer;
a gate electrode overlapping the semiconductor layer; and
source and drain electrodes electrically connected to the semiconductor layer, and
wherein the pad electrode comprises a same material as the source and drain electrodes.

14. The display device of claim 1, further comprising a metal pattern on an upper surface of the pad electrode exposed by the first opening,
wherein the metal pattern comprises a same material as the pad upper electrode.

15. A manufacturing method of a display device, comprising:
preparing a substrate in which a display area and a pad area are defined;
forming a thin film transistor located on the substrate and overlapping the display area, and a pad electrode located on the substrate and overlapping the pad area;
forming a via insulating layer in the display area and covering the thin film transistor;
forming a first alignment electrode and a second alignment electrode spaced from each other on the via insulating layer in the display area and forming a pad upper electrode material layer covering the pad electrode in the pad area;
forming a pad upper electrode including a first opening exposing the pad electrode by peeling off a portion of the pad upper electrode material layer overlapping the pad electrode; and
disposing a light emitting element on a space between the first alignment electrode and the second alignment electrode that are spaced from each other.

16. The method of claim 15, further comprising forming a first insulating layer covering the first alignment electrode and the second alignment electrode in the display area and including a second opening exposing the pad upper electrode material layer in the pad area.

17. The method of claim 16, further comprising forming an external bank on the first insulating layer, the external bank defining an emission area in which the light emitting element is located,
wherein the forming of the pad upper electrode is performed after the forming of the external bank.

18. The method of claim 15, wherein the forming of the thin film transistor and the pad electrode comprises forming a passivation layer covering the thin film transistor in the display area and including a second opening exposing a portion of the pad electrode in the pad area, and
wherein the pad upper electrode material layer covers the passivation layer and a portion of the pad electrode exposed by the second opening in the pad area.

19. The method of claim 18, wherein an adhesive force between the pad upper electrode material layer and the pad electrode is smaller than an adhesive force between the pad upper electrode material layer and the passivation layer.

20. The method of claim 19, wherein the peeling-off of the portion of the pad upper electrode material layer overlapping the pad electrode is performed by a mechanical peeling using a tape.
